(19) United States
(12) Patent Application Publication
(10) Pub. No.: US 2025/0228020 A1
(43) Pub. Date: Jul. 10, 2025

(54) PHOTODETECTOR AND ELECTRONIC APPARATUS

(71) Applicant: SONY SEMICONDUCTOR SOLUTIONS CORPORATION, Kanagawa (JP)

(72) Inventor: Shouichirou SHIRAISHI, Kumamoto (JP)

(73) Assignee: SONY SEMICONDUCTOR SOLUTIONS CORPORATION, Kanagawa (JP)

(21) Appl. No.: 18/852,645

(22) PCT Filed: Mar. 27, 2023
(86) PCT No.: PCT/JP2023/012253

§ 371 Date: Sep. 30, 2024

(30) Foreign Application Priority Data
Apr. 28, 2022 (JP) 2022-075167

(51) Int. Cl. H10F 39/18; H04N 25/62; H04N 25/772; H10F 39/00

(52) U.S. Cl. CPC H10F 39/18; H10F 39/80373; H10F 39/806; H10F 39/807; H04N 25/62; H04N 25/772

(57) ABSTRACT

To ensure stable transfer capability. A photodetector includes a semiconductor layer having a first surface and a second surface located on opposite sides, a photoelectric conversion unit in the semiconductor layer that converts, through photoelectric conversion, light incident from a second surface side of the semiconductor layer, a charge holding unit on a first surface side of the semiconductor layer, a transfer transistor that includes a gate electrode and that transfers signal charge generated by the photoelectric conversion unit through the photoelectric conversion to the charge holding unit, and an isolation region on the first surface side of the semiconductor layer. The gate electrode includes a head on the first surface side of the semiconductor layer and legs that extend from the head in a thickness direction of the semiconductor layer and that are in the isolation region adjacent to the semiconductor layer via a gate insulating film.

### TECHNICAL FIELD

The present technology (technology of the present disclosure) relates to a photodetector and an electronic apparatus, and more particularly relates to a technology effective when applied to a photodetector including a transfer transistor and an electronic apparatus including the photodetector.

### BACKGROUND ART

A photodetector such as a solid-state imaging device or a ranging device includes, for each of pixels, a transfer transistor that transfers signal charge generated by a photoelectric conversion unit through photoelectric conversion to a charge holding unit. Patent Document 1 discloses a transfer transistor having a vertical structure in which a part (body) of a gate electrode is embedded in a groove of a substrate via a gate insulating film. Furthermore, Patent Document 2 discloses an imaging device in which a groove for shallow trench isolation (STI) is formed in a substrate, pinning of STI sidewalls is enhanced during accumulation by applying a voltage to an embedded polysilicon electrode embedded in the groove via an insulating film, and transfer of signal charge is improved during the transfer by applying a voltage to pixel region p-wells and the embedded polysilicon electrode.

### CITATION LIST

### Patent Document

Patent Document 1: Japanese Patent Application Laid-Open No. 2018-120804
Patent Document 2: Japanese Patent Application Laid-Open No. 2006-120804

### SUMMARY OF THE INVENTION

### Problems to be Solved by the Invention

During these years, by the way, since high-resolution image sensors are demanded in the market, image sensors with reduced pixel sizes are being developed.

When the pixel size decreases, however, transfer capability of a transfer transistor that transfers signal charge generated by a photoelectric conversion unit through photoelectric conversion to a charge holding unit decreases. A transfer transistor having a vertical structure is considered to be advantageous for transfer of signal charge as compared with a transfer transistor having a planar structure, but it is becoming difficult to secure robust (stable) transfer capability even in an existing transfer transistor having a vertical structure.

An object of the present technology is to ensure stable transfer capability.

### Solutions to Problems

A photodetector according to an aspect of the present technology includes

a semiconductor layer having a first surface and a second surface located on opposite sides,

a photoelectric conversion unit that is provided in the semiconductor layer and that converts, through photoelectric conversion, light incident from a second surface side of the semiconductor layer,

a charge holding unit provided on a first surface side of the semiconductor layer,

a transfer transistor that includes a gate electrode and that transfers signal charge generated by the photoelectric conversion unit through the photoelectric conversion to the charge holding unit, and

an isolation region provided on the first surface side of the semiconductor layer.

In addition, the gate electrode includes

a head provided on the first surface side of the semiconductor layer and

legs that extend from the head in a thickness direction of the semiconductor layer and that are provided in the isolation region adjacent to the semiconductor layer via a gate insulating film.

An electronic apparatus according to another aspect of the present technology includes

the photodetector,

an optical lens that forms an image of image light from a subject on an imaging surface of the photodetector, and

a signal processing circuit that performs signal processing on a signal output from the photodetector.

### BRIEF DESCRIPTION OF DRAWINGS

FIG. 1 is a chip layout diagram illustrating a configuration example of a solid-state imaging device according to a first embodiment of the present technology.

FIG. 2 is a block diagram illustrating a circuit configuration example of the solid-state imaging device according to the first embodiment of the present technology.

FIG. 3A is an equivalent circuit diagram illustrating an example of a pixel unit of the solid-state imaging device according to the first embodiment of the present technology.

FIG. 3B is a schematic plan view illustrating two pixel blocks included in a pixel block group in FIG. 3A.

FIG. 4 is a schematic plan view in which one of the two pixel blocks in FIG. 3B is enlarged.

FIG. 5 is a schematic vertical sectional view illustrating a vertical sectional structure taken along a line a4-a4 in FIG. 4.

FIG. 6 is a schematic enlarged sectional view in which a part of FIG. 5 is enlarged.

FIG. 7 is a schematic vertical sectional view illustrating a vertical sectional structure taken along a line b4-b4 in FIG. 4.

FIG. 8 is a diagram illustrating a horizontal sectional pattern of a pixel isolation region in a horizontal section perpendicular to a thickness direction of a semiconductor layer.

FIG. 9 is a schematic plan view in which a charge transfer path and a virtual line are shown in FIG. 4.

FIG. 10 is a schematic vertical sectional view illustrating the charge transfer path when a transfer transistor is in an on state.

FIG. 11 is a diagram illustrating a potential of signal charge in a transfer path when a transfer transistor of a pixel in a comparative example is in an on state and a potential of signal charge in a transfer path when a transfer transistor of a pixel in the present technology is in an on state.

FIG. 12A is a schematic process cross-sectional view illustrating a method for manufacturing the solid-state imaging device according to the first embodiment of the present technology.

FIG. 12B is a schematic process cross-sectional view following FIG. 12A.

FIG. 12C is a schematic process cross-sectional view following FIG. 12B.

FIG. 12D is a schematic process cross-sectional view following FIG. 12C.

FIG. 12E is a schematic process cross-sectional view following FIG. 12D.

FIG. 12F is a schematic process cross-sectional view following FIG. 12E.

FIG. 12G is a schematic process cross-sectional view following FIG. 12F.

FIG. 12H is a schematic process cross-sectional view following FIG. 12G.

FIG. 13 is a schematic plan view illustrating a pixel block of a solid-state imaging device according to a second embodiment of the present technology.

FIG. 14 is a schematic vertical sectional view illustrating a vertical sectional structure taken along a line a13-a13 in FIG. 13.

FIG. 15 is a schematic plan view illustrating a pixel block of a solid-state imaging device according to a third embodiment of the present technology.

FIG. 16 is a schematic vertical sectional view illustrating a vertical sectional structure taken along a line a15-a15 in FIG. 15.

FIG. 17 is a schematic plan view illustrating a pixel block of a solid-state imaging device according to a fourth embodiment of the present technology.

FIG. 18 is a schematic vertical sectional view illustrating a vertical sectional structure taken along a line a17-a17 in FIG. 17.

FIG. 19 is a schematic plan view illustrating a pixel block of a solid-state imaging device according to a fifth embodiment of the present technology.

FIG. 20 is a schematic vertical sectional view illustrating a vertical sectional structure taken along a line a19-a19 in FIG. 19.

FIG. 21 is a schematic plan view illustrating a pixel block of a solid-state imaging device according to a sixth embodiment of the present technology.

FIG. 22 is a schematic vertical sectional view illustrating a vertical sectional structure taken along a line a21-a21 in FIG. 21.

FIG. 23 is a diagram illustrating a configuration example of an electronic apparatus according to a seventh embodiment of the present technology.

FIG. 24 is a block diagram illustrating a schematic configuration example of a vehicle control system.

FIG. 25 is an explanatory diagram illustrating an example of installation positions of an outside-vehicle information detecting section and imaging sections.

FIG. 26 is a block diagram illustrating a schematic configuration example of an endoscopic surgical system.

FIG. 27 is a block diagram illustrating an example of a functional configuration of a camera head and a CCU.

### MODE FOR CARRYING OUT THE INVENTION

Embodiments of the present technology will be described hereinafter in detail with reference to the drawings.

In the illustration of the drawings referred to in the following description, the same or similar parts are given the same or similar reference signs. It should be noted that the drawings are schematic, and a relationship between a thickness and a planar dimension, a ratio of thicknesses of individual layers, and the like are different from reality. Specific thicknesses and dimensions, therefore, should be determined in consideration of the following description.

Furthermore, it goes without saying that dimensional relationships and ratios are partly different between the drawings. Furthermore, the effects described herein are merely examples and are not limited, and other effects may also be produced.

Furthermore, the following embodiments illustrate apparatuses and methods for embodying the technical idea of the present technology, and do not limit configurations to those described below. That is, various modifications can be made to the technical idea of the present technology within the technical scope described in the claims.

Furthermore, the definitions of directions such as upward and downward in the following description are merely defined for convenience of description, and do not limit the technical idea of the present technology. It goes without saying, for example, that if a target is rotated by 90° and observed, upward and downward are converted into rightward and leftward, and if a target is rotated by 180° and observed, upward and downward are inverted.

Furthermore, in the following embodiments, a case will be described as an example where a first conductivity type is a p-type and a second conductivity type is an n-type. The conductivity types, however, may be selected in an opposite relationship, and the first conductivity type may be the n-type and the second conductivity type may be the p-type, instead.

Furthermore, in the following embodiments, among three directions perpendicular to each other in space, a first direction and a second direction perpendicular to each other in the same plane will be defined as an X direction and a Y direction, respectively, and a third direction perpendicular to the first direction and the second direction will be defined as a Z direction. In addition, in the following embodiments, a thickness direction of a semiconductor layer 20, which will be described later, will be described as the Z direction.

### First Embodiment

In a first embodiment, an example where the present technology is applied to a solid-state imaging device that is called a back-illuminated complementary metal-oxide-semiconductor (CMOS) image sensor will be described as a photodetector.

### Overall Configuration of Solid-State Imaging Device

First, an overall configuration of a solid-state imaging device 1A will be described.

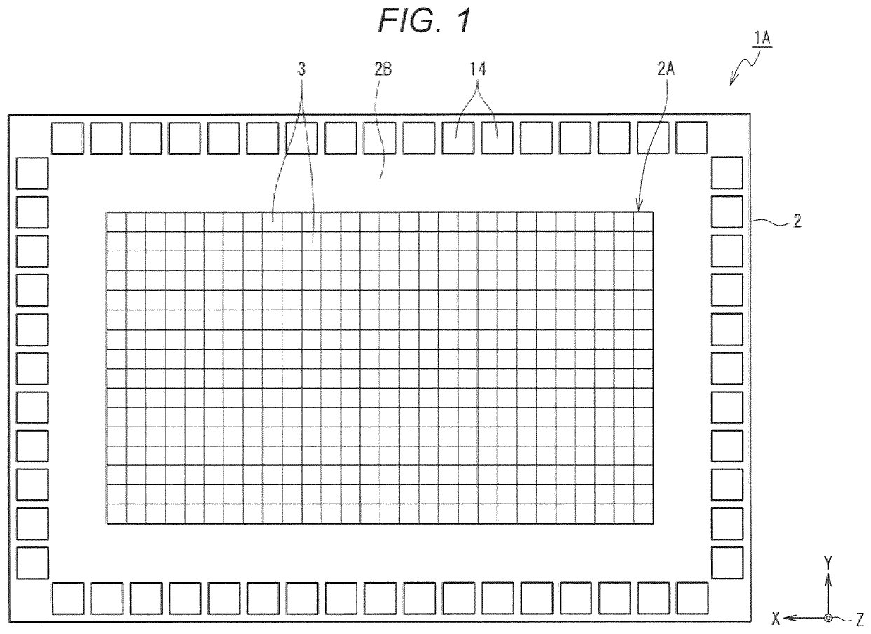

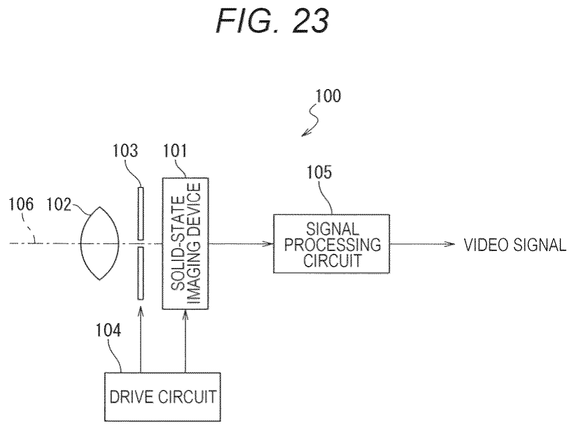

As illustrated in FIG. 1, the solid-state imaging device 1A according to the first embodiment of the present technology mainly includes a semiconductor chip 2 having a rectangular two-dimensional planar shape in plan view. That is, the solid-state imaging device 1A is mounted on the semiconductor chip 2, and the semiconductor chip 2 can be regarded as the solid-state imaging device 1A. As illustrated in FIG. 23, the solid-state imaging device 1A (101) receives image light (incident light 106) from a subject through an optical lens 102, converts an amount of the incident light 106 formed, as an image, on an imaging plane into an electrical signal for each pixel, and outputs the electrical signal as a pixel signal (image signal).

As illustrated in FIG. 1, the semiconductor chip 2 on which the solid-state imaging device 1A is mounted includes, in a two-dimensional plane including the X direction and the Y direction perpendicular to each other, a rectangular pixel array unit 2A provided in a central portion thereof and a peripheral portion 2B provided outside the pixel array unit 2A in such a way as to surround the pixel array unit 2A. The semiconductor chip 2 is formed in a manufacturing process by cutting a semiconductor wafer including the semiconductor layer 20, which will be described later, into small pieces for each of chip formation regions. The configuration of the solid-state imaging device 1A, which will be described below, therefore, is substantially similar to that before the semiconductor wafer is cut into small pieces. That is, the present technology is applicable to both a semiconductor chip and a semiconductor wafer.

The pixel array unit 2A is, for example, a light receiving surface that receives light condensed by the optical lens (optical system) 102 illustrated in FIG. 23. In addition, in the pixel array unit 2A, a plurality of pixels 3 is arranged in a matrix in the two-dimensional plane including the X direction and the Y direction. In other words, the pixels 3 are repeatedly arranged in the X direction and the Y direction perpendicular to each other in the two-dimensional plane.

As illustrated in FIG. 1, a plurality of bonding pads 14 is arranged in the peripheral portion 2B. Each of the plurality of bonding pads 14 is disposed, for example, along one of four sides of the two-dimensional plane of the semiconductor chip 2. Each of the plurality of bonding pads 14 functions as an input/output terminal that electrically connects the semiconductor chip 2 and an external device to each other.

### Logic Circuit

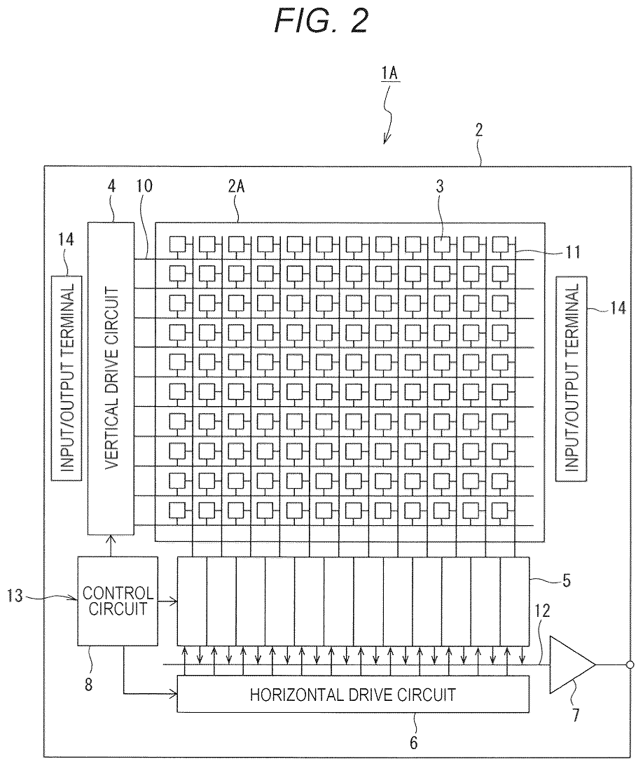

The semiconductor chip 2 includes a logic circuit 13 illustrated in FIG. 2. As illustrated in FIG. 2, the logic circuit 13 includes a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel metal-oxide-semiconductor field-effect transistor (MOSFET) and a p-channel MOSFET as field-effect transistors.

The vertical drive circuit 4 includes, for example, a shift register. The vertical drive circuit 4 sequentially selects desired pixel drive lines 10 and supplies pulses for driving the pixels 3 to the selected pixel drive lines 10 to drive the individual pixels 3 row by row. That is, the vertical drive circuit 4 selectively scans the individual pixels 3 in the pixel array unit 2A sequentially in a vertical direction on a row-by-row basis and supplies a pixel signal from each of the pixels 3 based on signal charge generated by a photoelectric conversion unit (photoelectric conversion element) of the pixel 3 in accordance with the amount of light received to the corresponding column signal processing circuit 5 through a corresponding vertical signal line 11.

The column signal processing circuit 5 is disposed for each column of the pixels 3, for example, and performs, for the pixel column, signal processing such as noise removal on signals output from the pixels 3 in one column. For example, the column signal processing circuits 5 perform signal processing such as correlated double sampling (CDS) for removing pixel-specific fixed pattern noise and analog-digital (AD) conversion.

The horizontal drive circuit 6 includes, for example, a shift register. The horizontal drive circuit 6 sequentially outputs horizontal scanning pulses to the column signal processing circuits 5 to sequentially select the individual column signal processing circuits 5, and causes the individual column signal processing circuits 5 to output pixel signals subjected to the signal processing to the horizontal signal line 12.

The output circuit 7 performs signal processing on the pixel signals sequentially supplied from the individual column signal processing circuits 5 through the horizontal signal line 12, and outputs the pixel signals. As the signal processing, for example, buffering, black level adjustment, column variation correction, various types of digital signal processing, and the like may be used.

The control circuit 8 generates a clock signal and a control signal that serve as references for operations of the vertical drive circuit 4, the column signal processing circuits 5, the horizontal drive circuit 6, and the like on the basis of a vertical synchronization signal, a horizontal synchronization signal, and a master clock signal. The control circuit 8 then outputs the generated clock signal and control signal to the vertical drive circuit 4, the column signal processing circuits 5, the horizontal drive circuit 6, and the like.

### Pixel Unit

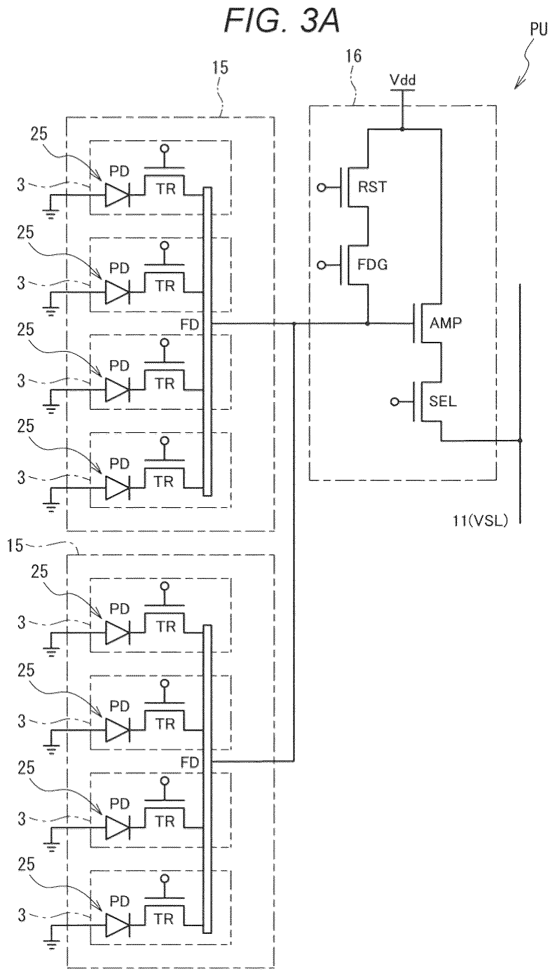

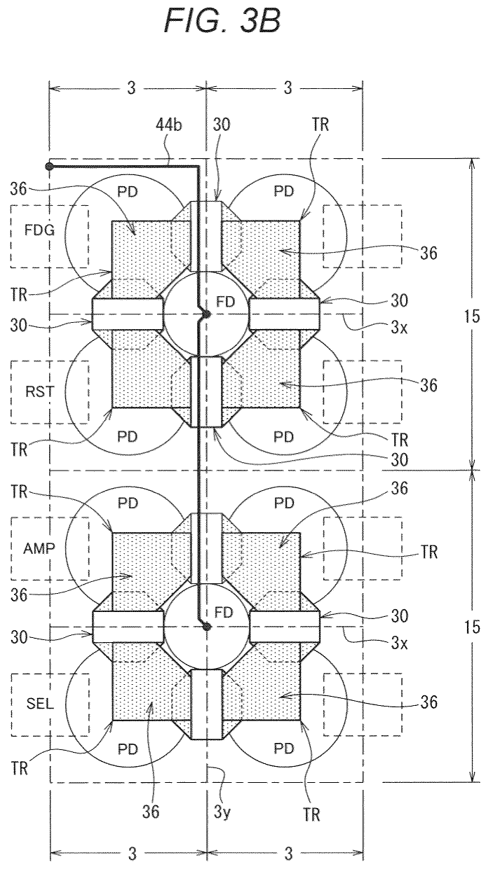

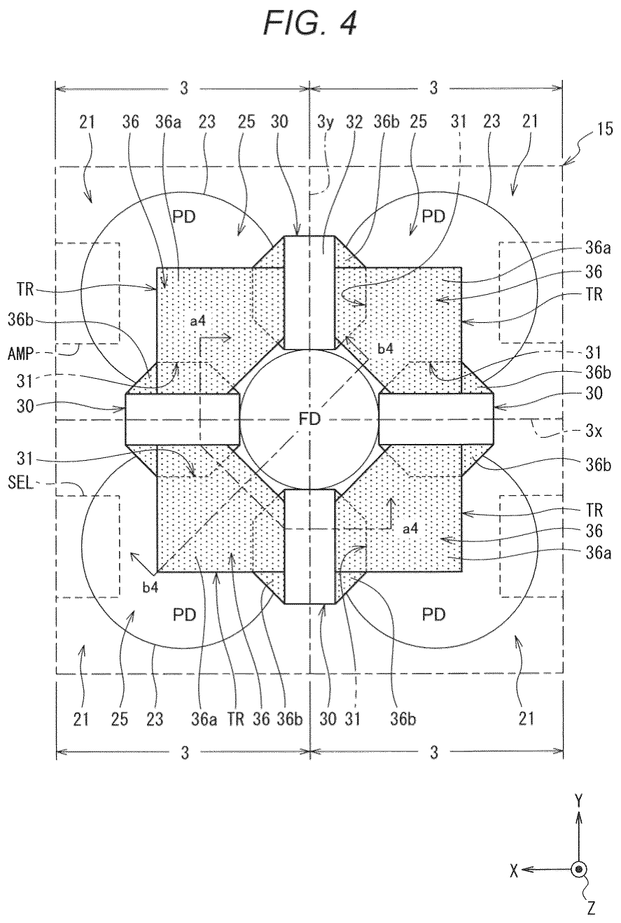

The semiconductor chip 2 includes the pixel unit PU illustrated in FIG. 3A. The pixel unit PU includes, but is not limited to, two pixel blocks 15 and one pixel circuit (reading circuit) 16, for example, as illustrated in FIGS. 3A and 3B. As illustrated in FIG. 3B, for example, the two pixel blocks 15 are arranged adjacent to each other in the Y direction to constitute one pixel block group. In addition, as illustrated in FIG. 4, for example, each of the two pixel blocks 15 includes, but not limited to, four pixels 3, two of which are arranged adjacent to each other in each of the X direction and the Y direction in plan view and a floating diffusion FD as one charge holding unit shared by the four pixels 3. That is, one pixel block group including two pixel blocks 15 includes eight pixels 3 and two floating diffusions FD.

Here, in the first embodiment, the floating diffusion FD corresponds to a specific example of a “charge holding unit” in the present technology.

As illustrated in FIG. 3A, an input stage of one pixel circuit 16 is electrically connected to the floating diffusion FD of each pixel block 15. In addition, an output of each of the four pixels 3 of each pixel block 15 is input to the input stage of the common pixel circuit 16. That is, in the first embodiment, a circuit configuration in which one pixel circuit 16 is allocated to two pixel blocks 15 (one pixel block group) is employed, although the circuit configuration to be employed is not limited to this.

Each of the four pixels 3 included in one pixel block 15 includes the same components.

As illustrated in FIG. 3A, each of the four pixels 3 included in one pixel block 15 includes a photoelectric conversion unit 25, a floating diffusion FD that holds (accumulates) signal charge generated by the photoelectric conversion unit 25 as a result of photoelectric conversion, and a transfer transistor TR that transfers, to the floating diffusion FD, the signal charge generated by the photoelectric conversion unit 25 as a result of the photoelectric conversion.

Each photoelectric conversion unit 25 illustrated in FIG. 3A is a photodiode (PD) of a p-n junction type, for example, and generates signal charge according to the amount of light received. The photoelectric conversion unit 25 has a cathode side electrically connected to a source region of the transfer transistor TR and an anode side electrically connected to a reference potential line (e.g., ground). A drain region of the transfer transistor TR is electrically connected to the floating diffusion FD.

The transfer transistor TR illustrated in FIG. 3A transfers the signal charge generated by the photoelectric conversion unit 25 as a result of photoelectric conversion to the floating diffusion FD. A source region of the transfer transistor TR is electrically connected to the cathode side of the photoelectric conversion unit 25, and the drain region of the transfer transistor TR is electrically connected to the floating diffusion FD. In addition, a gate electrode of the transfer transistor TR is electrically connected to a transfer transistor drive line among the pixel drive lines 10 (see FIG. 2).

Each floating diffusion FD illustrated in FIG. 3A temporarily holds (accumulates) signal charges transferred from the corresponding photoelectric conversion units 25 via the corresponding transfer transistors TR.

The pixel circuit 16 illustrated in FIG. 3A reads signal charges held in the floating diffusions FD and outputs pixel signals based on the signal charges. In other words, the pixel circuit 16 converts the signal charges generated by the photoelectric conversion units 25 as a result of photoelectric conversion into pixel signals based on the signal charges and outputs the pixel signals.

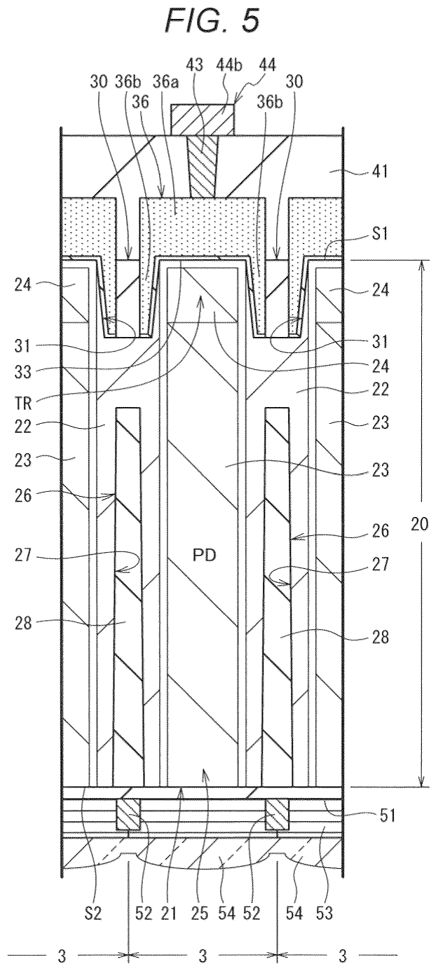

The photoelectric conversion units 25, the transfer transistors TR, and the floating diffusions FD are provided in a photoelectric conversion region 21 (see FIGS. 5 to 7) of a semiconductor layer 20 described later.

The pixel circuit 16 illustrated in FIG. 3A reads signal charges held in the floating diffusions FD and outputs pixel signals based on the signal charges. The pixel circuit 16 includes, for example, an amplifier transistor AMP, a selection transistor SEL, a reset transistor RST, and a selection transistor FDG as pixel transistors, although the pixel circuit 16 is not limited to this. Each of these pixel transistors (AMP, SEL, RST, and FDG) is, as a field-effect transistor, a MOSFET including, for example, a gate insulating film formed by a silicon oxide (SiO₂) film, a gate electrode, and a pair of main electrode regions that functions as a source region and a drain region. Alternatively, these pixel transistors may each be a metal-insulator-semiconductor FET (MISFET) whose gate insulating film is a silicon nitride (Si₃N₄) film or a multilayer film of a silicon nitride film and a silicon oxide film.

The amplifier transistor AMP illustrated in FIG. 3A has a source region electrically connected to a drain region of the selection transistor SEL and a drain region electrically connected to a power supply line Vdd and a drain region of the reset transistor RST. In addition, a gate electrode of the amplifier transistor AMP is electrically connected to the floating diffusions FD and a source region of the switching transistor FDG.

The selection transistor SEL illustrated in FIG. 3A has a source region electrically connected to the corresponding vertical signal line 11 (VSL) and a drain region electrically connected to the source region of the amplifier transistor AMP. In addition, a gate electrode of the selection transistor SEL is electrically connected to a selection transistor drive line among the pixel drive lines 10 (see FIG. 2).

The reset transistor RST illustrated in FIG. 3A has a source region electrically connected to a drain region of the switching transistor FDG and the drain region electrically connected to the power supply line Vdd and the drain region of the amplifier transistor AMP. In addition, a gate electrode of the reset transistor RST is electrically connected to a reset transistor drive line among the pixel drive lines 10 (see FIG. 2).

The switching transistor FDG illustrated in FIG. 3A has the source region electrically connected to the floating diffusions FD and the gate electrode of the amplifier transistor AMP and the drain region electrically connected to the power supply line Vdd and the drain region of the amplifier transistor AMP. In addition, a gate electrode of the switching transistor FDG is electrically connected to a switching transistor drive line among the pixel drive lines 10 (see FIG. 2).

Note that the selection transistor SEL and the switching transistor FDG may be omitted as necessary. Note that in a case where the selection transistor SEL is omitted, the source region of the amplifier transistor AMP is electrically connected to the vertical signal line 11 (VSL). Furthermore, in a case where the switching transistor FDG is omitted, the source region of the reset transistor RST is electrically connected to the gate electrode of the amplifier transistor AMP and the floating diffusions FD.

When each transfer transistor TR illustrated in FIG. 3A is turned on, the transfer transistor TR transfers signal charge generated by the photoelectric conversion unit 25 (photoelectric conversion element PD) to the floating diffusion FD.

When each reset transistor RST illustrated in FIG. 3A is turned on, the reset transistor RST resets a potential (signal charge) of the floating diffusion FD to a potential of the power supply line Vdd. The selection transistor SEL controls output timing of pixel signals from the pixel circuit 16.

The amplifier transistor AMP illustrated in FIG. 3A generates a signal of a voltage corresponding to a level of signal charge held by the floating diffusion FD as a pixel signal. The amplifier transistor AMP constitutes a source follower amplifier and outputs a pixel signal of a voltage corresponding to a level of signal charge generated by the photoelectric conversion unit 25 (photoelectric conversion element PD). When the selection transistor SEL is turned on, the amplifier transistor AMP amplifies the potential of the floating diffusion FD, and outputs a voltage corresponding to the potential to the corresponding column signal processing circuit 5 through the vertical signal line 11 (VSL).

The switching transistor FDG illustrated in FIG. 3A controls charge holding of the charge holding region FD and adjusts an amplification factor of the voltage according to the potential amplified by the amplifier transistors AMP.

During the operation of the solid-state imaging device 1A according to the first embodiment, signal charge generated by the photoelectric conversion unit 25 of the pixel 3 is held (accumulated) in the floating diffusion FD via the transfer transistor TR of the pixel 3. The signal charge held by the floating diffusion FD is then read by the pixel circuit 16 and applied to the gate electrode of the amplifier transistor AMP of the pixel circuit 16. A vertical shift register supplies a horizontal line selection control signal to the gate electrode of the selection transistor SEL of the pixel circuit 16. In addition, by setting the selection control signal to a high (H) level, the selection transistor SEL is conducted, and a current corresponding to the potential of the floating diffusion FD amplified by the amplifier transistor AMP flows through the vertical signal line 11. Furthermore, by setting a reset control signal applied to the gate electrode of the reset transistor RST of the pixel circuit 16 to the high (H) level, the reset transistor RST is conducted, and the signal charge accumulated in the floating diffusion FD is reset.

The photoelectric conversion units 25, the transfer transistors TR, and the floating diffusions FD illustrated in FIG. 3A are provided in the semiconductor layer 20 (see FIG. 4), which will be described later. Furthermore, although not limited to this, the pixel transistors (AMP, SEL, RST, and FDG) included in the pixel circuit 16 illustrated in FIG. 3A, for example, are also provided in the semiconductor layer 20.

### Specific Configuration of Solid-State Imaging Device

Next, a specific configuration of the semiconductor chip 2 (solid-state imaging device 1A) will be described with reference to FIGS. 4 to 10.

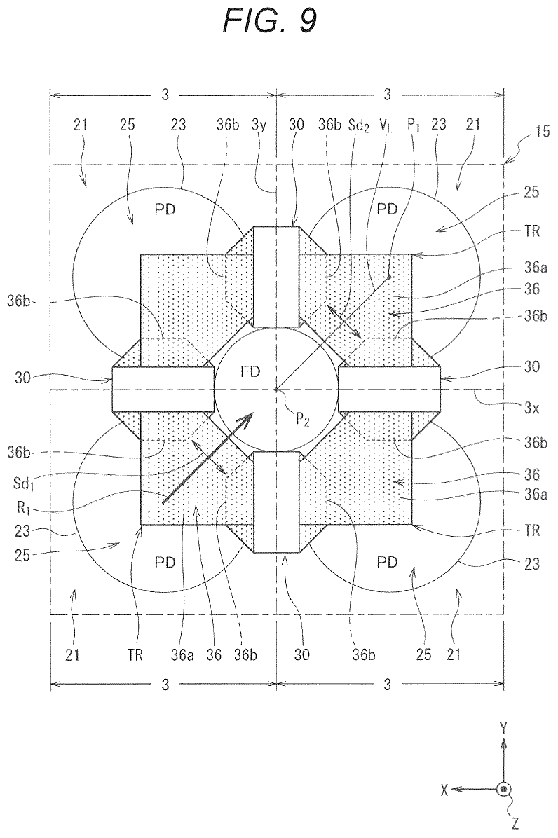

For convenience of description, FIGS. 4 to 10 are vertically inverted with respect to FIG. 1. Furthermore, in FIGS. 4 and 9, illustration of layers higher than a gate electrode 36 is omitted.

As illustrated in FIGS. 4 to 7, the semiconductor chip 2 includes a semiconductor layer 20 having a first surface S1 and a second surface S2 located on opposite sides and a photoelectric conversion unit 25 that is provided in the semiconductor layer 20 and that performs photoelectric conversion on light incident from a second surface S2 side of the semiconductor layer 20.

Furthermore, the semiconductor chip 2 includes the floating diffusion FD and the gate electrode 36 provided on a first surface S1 side of the semiconductor layer 20, and further includes the transfer transistor TR that transfers the signal charge subjected to the photoelectric conversion in the photoelectric conversion unit 25 to the floating diffusion FD and an element isolation region 30 as an isolation region provided on the first surface S1 side of the semiconductor layer 20.

Furthermore, the semiconductor chip 2 further includes a multilayer wiring layer including an interlayer insulating film 41 and a wiring layer 44 provided on the first surface S1 side of the semiconductor layer 20.

Furthermore, the semiconductor chip 2 further includes, on the second surface S2 side of the semiconductor layer 20, a planarization film 51, a light shielding film 52, an optical filter 53, and a microlens (on-chip lens) 54 sequentially provided from the second surface S2 side.

Here, the first surface S1 of the semiconductor layer 20 will also be referred to as a main surface or an element formation surface, and the second surface S2 will also be referred to as a back surface. In addition, in the solid-state imaging device 1A according to the first embodiment, light incident from the second surface S2 side of the semiconductor layer 20 is subjected to photoelectric conversion in the photoelectric conversion unit 25 (photoelectric conversion element PD) provided in the semiconductor layer 20. In the first embodiment, therefore, the second surface S2 of the semiconductor layer 20 will also be referred to as a light incident surface.

Furthermore, in the first embodiment, the element isolation region 30 corresponds to a specific example of an “isolation region” of the present technology.

As illustrated in FIG. 4, two of the four pixels 3 included in each pixel block 15 are arranged in each of the X direction and the Y direction in plan view, and laid out in 2×2 arrangement. That is, in the pixel array 2A illustrated in FIG. 1 referred to above, a pixel block 15 including four pixels 3 as a unit is repeatedly arranged in each of the X direction and the Y direction. In other words, in the pixel array 2A illustrated in FIG. 1 referred to above, a pixel block group including two pixel blocks 15 arranged adjacent to each other in the Y direction is repeatedly arranged in each of the X direction and the Y direction.

### Planarization Film, Light Shielding Film, Optical Filter, and Microlens

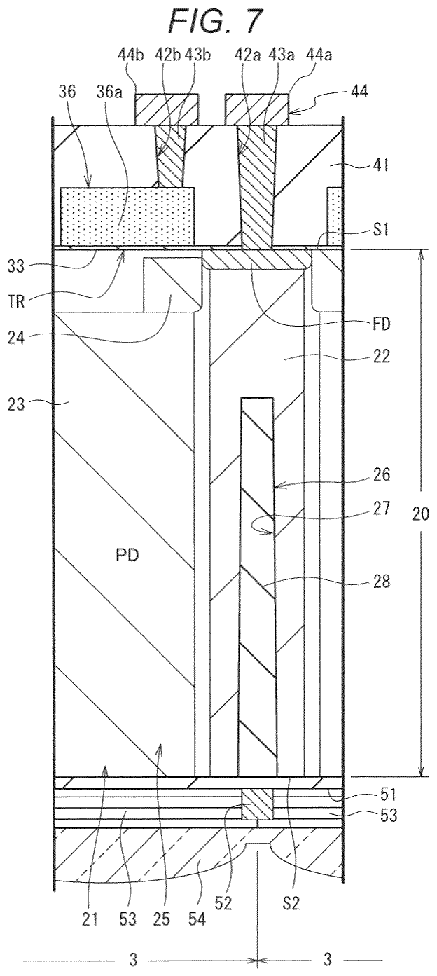

The planarization film 51 illustrated in FIGS. 5 and 7 is provided on the second surface S2 side of the semiconductor layer 20 in such a way as to cover the second surface S2 of the semiconductor layer 20, and planarizes the second surface S2 side of the semiconductor layer 20.

The light shielding film 52 illustrated in FIGS. 5 and 7 has, when viewed in plan, a planar pattern that is a lattice-shaped planar pattern so that adjacent pixels 3 are separated from each other.

The optical filter 53 and the microlens 54 illustrated in FIGS. 5 and 7 are provided for each pixel 3. The optical filter 53 color-separates incident light incident from a light incident surface side (second surface S2 side) of the semiconductor chip 2. The microlens 54 condenses radiated light and allows the condensed light to efficiently enter the pixel 3.

### Semiconductor Layer

As illustrated in FIGS. 5 to 7, the semiconductor layer 20 includes a pixel isolation region 26 and a photoelectric conversion region 21 defined by the pixel isolation region 26. The photoelectric conversion region 21 is provided for each pixel 3. As the semiconductor layer 20, a Si substrate, a SiGe substrate, an InGaAs substrate, or the like may be used. In the first embodiment, although not limited to this, a p-type semiconductor substrate formed by, for example, single crystal silicon is used as the semiconductor layer 20.

### Pixel Isolation Region

As illustrated in FIGS. 5 to 7, the pixel isolation region 26 extends from the second surface S2 side of the semiconductor layer 20 along the thickness direction (Z direction) of the semiconductor layer 20, and is separated from the element isolation region 30 provided on the first surface S2 side of the semiconductor layer 20. The pixel isolation region 26 includes a recess 27 extending in the thickness direction (Z direction) of the semiconductor layer 20 from the second surface S2 side of the semiconductor layer 20 and an isolation insulating film 28 provided in the recess 27. The isolation insulating film 28 is, for example, a silicon oxide film.

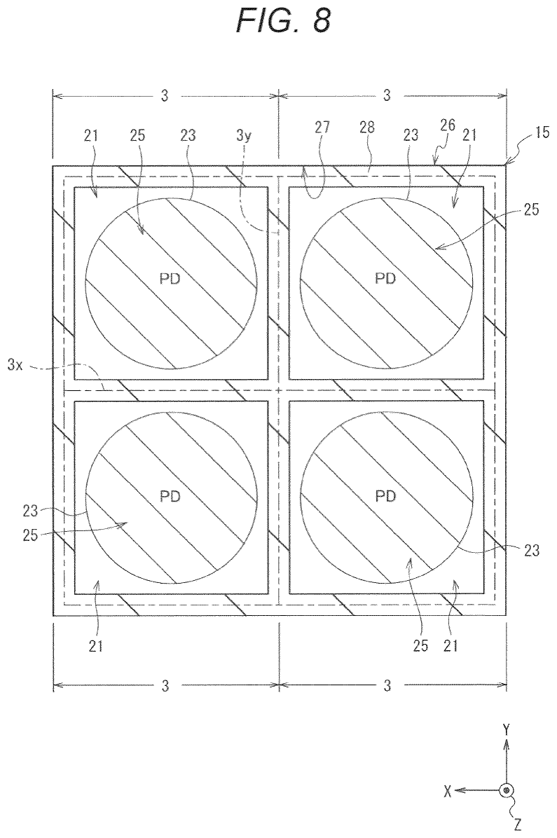

As illustrated in FIG. 8, the pixel isolation region 26 for one photoelectric conversion region 21 has, when viewed in plan, a planar pattern that is a rectangular annular planar pattern (ring-shaped planar pattern). In addition, the pixel isolation region 26 for the four photoelectric conversion regions 21 included in one pixel block 15 has, when viewed in plan, a composite planar pattern including a lattice-shaped planar pattern in which a pixel isolation region 26 extending in the X direction and a pixel isolation region 26 extending in the Y direction intersect in a rectangular annular planar pattern surrounding the periphery of the four photoelectric conversion regions 21 in plan view.

As illustrated in FIG. 8, when viewed in plan, the pixel isolation region 26 extends along the X direction on a virtual boundary line 3x between two pixels 3 adjacent to each other in the Y direction, and extends along the Y direction on a virtual boundary line 3y between two pixels 3 adjacent to each other in the X direction.

### Photoelectric Conversion Region

As illustrated in FIGS. 4 to 7, the photoelectric conversion region 21 is provided for each pixel 3. Each photoelectric conversion region 21 includes the photoelectric conversion unit 25, the floating diffusion FD, and the transfer transistor TR described above. Furthermore, each photoelectric conversion region 21 includes a p-type semiconductor region 22 as a first conductivity type and an n-type semiconductor region 23 as a second conductivity type. Furthermore, each photoelectric conversion region 21 includes an overflow drain region 24.

### Semiconductor Region and Overflow Drain Region

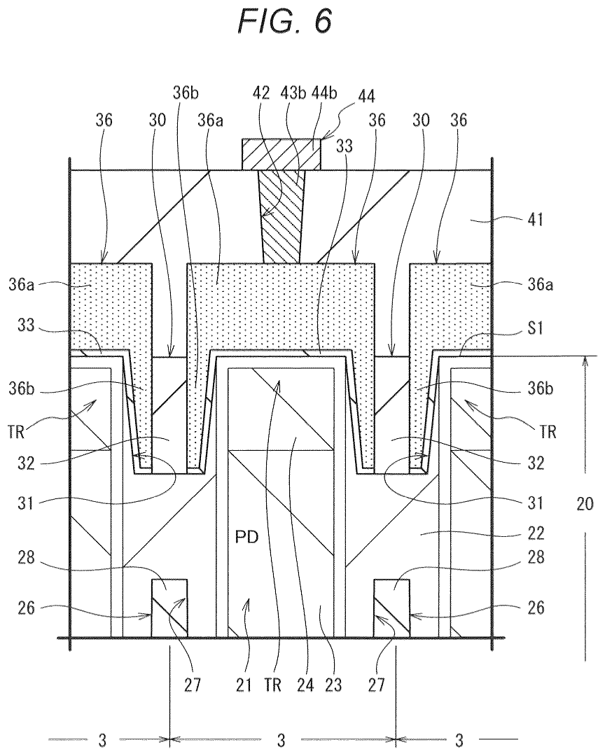

As illustrated in FIGS. 5 to 7, the p-type semiconductor region 22 extends along the thickness direction (Z direction) of the semiconductor layer 20 in such a way as to surround the pixel isolation region 26. In addition, the p-type semiconductor region 22 is in contact with an upper surface and a side surface of the pixel isolation region 26, the element isolation region 30 as illustrated in FIGS. 5 and 6, and the floating diffusion FD as illustrated in FIG. 7.

As illustrated in FIGS. 5 to 7, the n-type semiconductor region 23 extends from the second surface S2 side toward the first surface S1 side of the semiconductor layer 20 between two pixel isolation regions 26. In addition, the n-type semiconductor region 23 is separated from the p-type semiconductor region 22 and is separated from the first surface S1 of the semiconductor layer 20.

As illustrated in FIGS. 5 to 7, the overflow drain region 24 is provided between the n-type semiconductor region 23 and the first surface S1 of the semiconductor layer 20. In addition, the overflow drain region 24 is in contact with the n-type semiconductor region 23 and is separated from the first surface S1 of the semiconductor layer 20. The overflow drain region 24 is, for example, an n-type semiconductor region having an impurity concentration lower than that of the n-type semiconductor region 23.

Here, the photoelectric conversion unit 25 described above mainly includes the n-type semiconductor region 23 and is achieved as a p-n junction photodiode (PD) based on a p-n junction between the p-type semiconductor region 22 and the n-type semiconductor region 23.

### Floating Diffusion

As illustrated in FIGS. 4 and 7, the floating diffusion FD is disposed in a central portion of the pixel block 15, which includes four pixels 3 arranged in a matrix. That is, the floating diffusion FD is disposed at an intersection in the pixel block 15 between the virtual boundary line 3x between two pixels 3 arranged adjacent to each other in the Y direction and the virtual boundary line 3y between two pixels 3 arranged adjacent to each other in the X direction.

As illustrated in FIG. 7, the floating diffusion FD is provided in a surface layer portion of the semiconductor layer 20 on the first surface S1 side. The floating diffusion FD is, for example, an n-type semiconductor region having an impurity concentration higher than that of the n-type semiconductor region 23.

### Element Isolation Region

Although not limited to this, four element isolation regions 30 are provided in the pixel block 15 in an interspersed manner as illustrated in FIG. 4. Two of the four element isolation regions 30 are arranged at positions overlapping the virtual boundary line 3x in plan view on both sides of the floating diffusion FD in the X direction. In addition, the other two element isolation regions 30 are arranged at positions overlapping the virtual boundary line 3y in plan view on both sides of the floating diffusion FD in the Y direction. That is, two element isolation regions 30 are arranged at positions overlapping the virtual boundary line 3x or positions overlapping the virtual boundary line 3y in such a way as to surround the floating diffusion FD in plan view. In other words, an element isolation region 30 is disposed between two photoelectric conversion regions 21 adjacent to each other in plan view.

As illustrated in FIGS. 5 and 6, the element isolation regions 30 are provided in the surface layer portion of the semiconductor layer 20 on the first surface S1 side. As illustrated in FIG. 6, each element isolation region 30 includes a recess (groove) 31 in the thickness direction (Z direction) of the semiconductor layer 20 from the first surface S1 side of the semiconductor layer 20 and an isolation insulating film 32 provided in the recess 31. That is, the element isolation regions 30 have a shallow trench isolation (STI) structure. The isolation insulating film 32 is, for example, a silicon oxide film.

### Transfer Transistor

As illustrated in FIGS. 4 to 7, the transfer transistor TR is provided on the first surface S1 side of the semiconductor layer 20. The transfer transistor TR includes a gate electrode 36 provided on the first surface S1 side of the semiconductor layer 20 and a gate insulating film 33 interposed between the gate electrode 36 and the semiconductor layer 20. Furthermore, the transfer transistor TR includes a photoelectric conversion unit 25 and a floating diffusion FD that function as a source region and a drain region.

### Gate Electrode

As illustrated in FIG. 4, the transfer transistor TR of each of the four photoelectric conversion regions 21 (four pixels 3) included in the pixel block 15 is disposed close to the floating diffusion FD side in plan view. In addition, the gate electrode 36 of each of the four transfer transistors TR is disposed close to the floating diffusion FD side to surround the floating diffusion FD.

As illustrated in FIGS. 4 to 7, the gate electrode 36 includes a head (planar electrode) 36a provided on the first surface S1 side of the semiconductor layer 20 via the gate insulating film 33 and legs (vertical electrodes) 36b extending from the head 36a along the thickness direction (Z direction) of the semiconductor layer 20 and provided in the element isolation regions 30 adjacent to the semiconductor layer 20 via the gate insulating film 33. The head 36a of the gate electrode 36 is provided in such a way as to overlap the photoelectric conversion unit 25 in plan view.

As illustrated in FIG. 9, the head 36a of the gate electrode 36 is disposed at a position where the transfer transistor TR overlaps a charge transfer path R₁ through which signal charge is transferred from the photoelectric conversion unit 25 (n-type semiconductor region 23) to the floating diffusion FD in plan view. In addition, the legs 36b of the gate electrode 36 are provided on two end sides of the head 36a in a direction (intersecting direction Sd₁) intersecting the charge transfer path R₁ in plan view. In other words, the head 36a of the gate electrode 36 is provided on the two end sides of the head 36a in a direction (intersecting direction Sd₂) intersecting a virtual line V_{L} connecting a central portion P₁ of the photoelectric conversion unit 25 (n-type semiconductor region 23) and a central portion P₂ of the floating diffusion FD in plan view. In yet other words, the legs 36b of the gate electrode 36 are disposed outside the charge transfer path R₁. In yet other words, the head 36a of the gate electrode 36 is disposed at a position overlapping the virtual line V_{L} connecting the central portion P₁ of the photoelectric conversion unit 25 (n-type semiconductor region 23) and the central portion P₂ of the floating diffusion FD in plan view. In addition, the legs 36b of the gate electrode 36 are disposed at positions deviated from the virtual line V_{L} in plan view.

The legs 36b of the gate electrode 36 are disposed on at least one of two sides intersecting a transfer direction of the charge transfer path R₁. Although not limited to this, one leg 36b of the gate electrode 36 is disposed on each side of the charge transfer path R₁ in the first embodiment.

One of the two legs 36b of the gate electrode 36 is provided in the element isolation region 30 located on the virtual boundary line 3x in plan view, and the other leg 36b is provided in the element isolation region 30 located on the virtual boundary line 3y in plan view.

### Charge Transfer Path

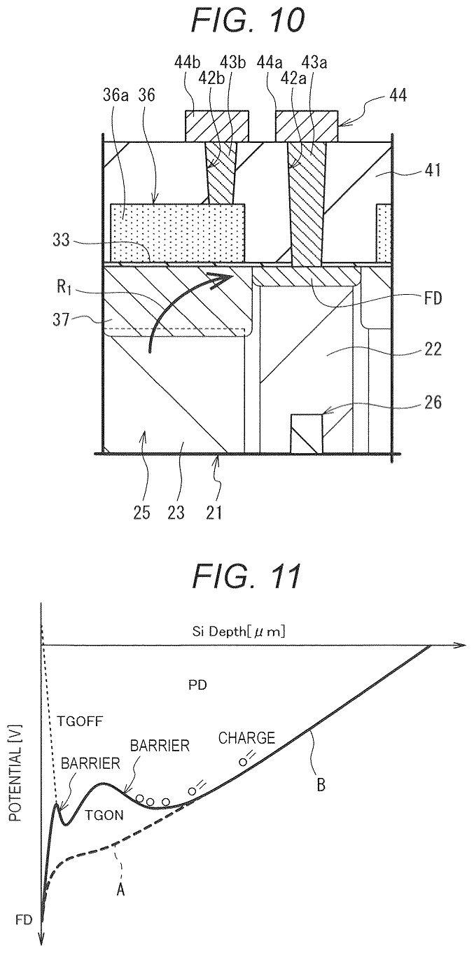

As illustrated in FIG. 10, in the transfer transistor TR, when the transfer transistor TR is turned on, deep inversion layers 37 are formed in the semiconductor layer 20 by the legs 36b of the gate electrode. The gate electrode 36 of the first embodiment has two legs 36b. In the transfer transistor TR of the first embodiment, therefore, two deep inversion layers 37 are formed in the semiconductor layer 20 by the two legs 36b of the gate electrode 36. In addition, a charge transfer path R₁ including the two inversion layers 37 is formed. In addition, signal charge generated by the photoelectric conversion unit 25 as a result of photoelectric conversion is transferred to the floating diffusion FD through the charge transfer path R₁. The transfer transistor TR according to the first embodiment is of a double lung type (dual type), in which the two legs 36b of the gate electrode 36 form two inversion layers 37 in the semiconductor layer 20.

### Pixel Transistors

As illustrated in FIG. 3B, an amplifier transistor AMP, a selection transistor SEL, a reset transistor RST, and a switching transistor FDG are provided for two pixel blocks 15 included in one pixel block group as pixel transistors included in the above-described pixel circuit 16. The gate electrode of each of these pixel transistors (AMP, SEL, RST, and FDG) is formed in the same layer as, for example, the gate electrode 36 of the transfer transistor TR.

### Multilayer Wiring Layer

As illustrated in FIGS. 5 to 7, the gate electrode 36 of the transfer transistor TR is covered by the interlayer insulating film 41 provided on the first surface S1 side of the semiconductor layer 20. Furthermore, although not illustrated in detail, the gate electrode of each of the plurality of pixel transistors (AMP, SEL, RST, and FDG) included in the above-described pixel circuit 16, too, is covered by the interlayer insulating film 41.

### Contact Electrodes and Wires

As illustrated in FIGS. 5 to 7, the gate electrode 36 of the transfer transistor TR is electrically connected to a wire 44b provided in the wiring layer 44 on the interlayer insulating film 41 via a contact electrode 43b provided in the interlayer insulating film 41. Furthermore, as illustrated in FIG. 7, the floating diffusion FD is electrically connected to a wire 44a provided in the wiring layer 44 on the interlayer insulating film 41 via a contact electrode 43a provided in the interlayer insulating film 41. The interlayer insulating film 41 is, for example, a silicon oxide film. As a material of the contact electrodes 43a and 43b, for example, tungsten (W), which is a high melting point metal, may be used. As a material of the wires 44a and 44b, for example, a metal material such as aluminum (Al) or copper (Cu), an alloy material mainly containing Al or Cu, or the like may be used.

### Method for Manufacturing Solid-State Imaging Device

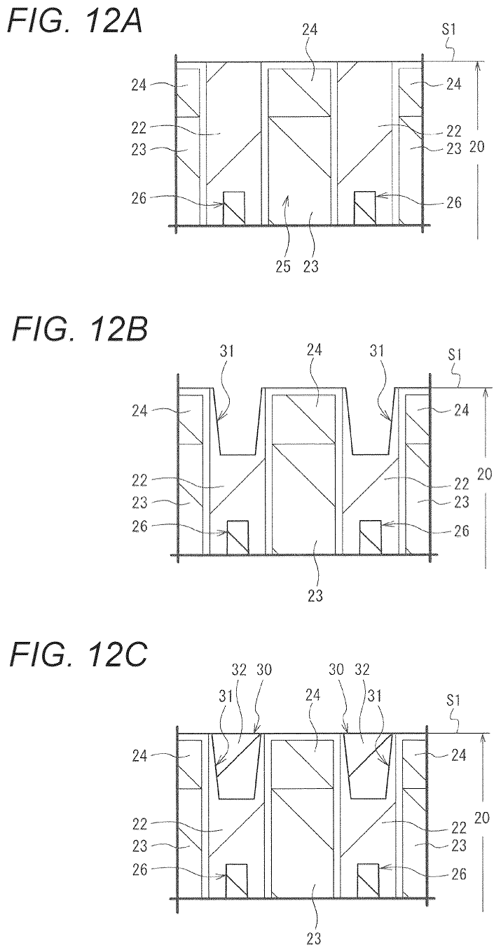

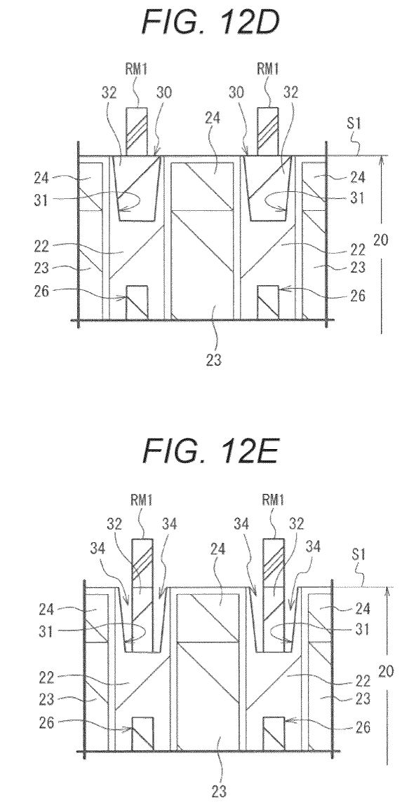

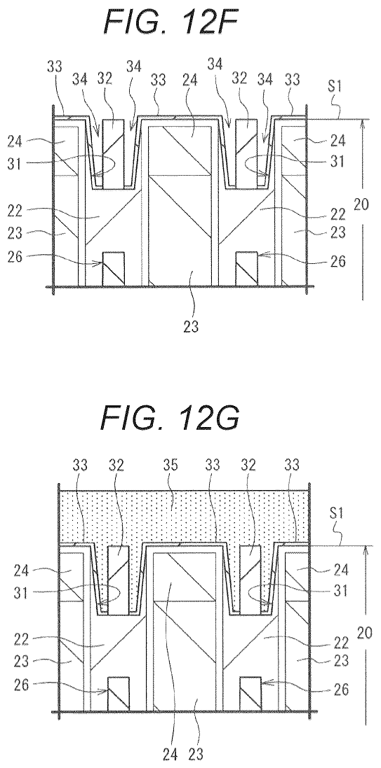

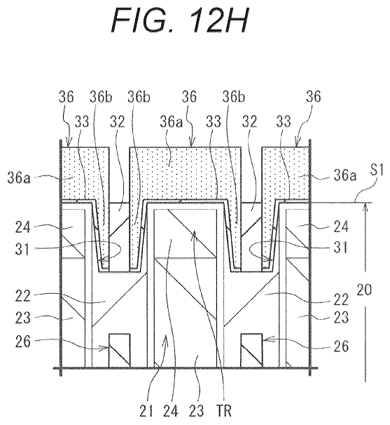

Next, a method of manufacturing the solid-state imaging device 1A will be described with reference to FIGS. 12A to 12H.

In the first embodiment, formation of the element isolation regions and the transfer transistors included in the method for manufacturing the solid-state imaging device will be mainly described.

First, as illustrated in FIG. 12A, the p-type semiconductor regions 22, the n-type semiconductor regions 23, the overflow drain regions 24, the photoelectric conversion units 25, and the pixel isolation regions 26 are formed in the semiconductor layer 20.

Next, as illustrated in FIG. 12B, the recesses 31 in the first surface S1 of the semiconductor layer 20 in the thickness direction (Z direction) of the semiconductor layer 20 are formed. The recesses 31 are formed at positions overlapping the virtual boundary line 3x and the virtual boundary line 3y illustrated in FIG. 4 in plan view. The recesses 31 are formed using a known photolithography technique and a known dry etching technique.

Next, as illustrated in FIG. 12C, the isolation insulating films 32 are formed in the recess 31. The isolation insulating films 32 can be formed by, for example, forming a silicon oxide film on an entire surface of the first surface S1 side of the semiconductor layer 20 including the inside of the recesses 31 by a CVD method and then selectively removing the silicon oxide film on the first surface S1 of the semiconductor layer 20 except for the silicon oxide film in the recesses 31.

Through this process, the element isolation regions 30 including the recesses 31 and the isolation insulating films 32 are formed at the positions overlapping the virtual boundary line 3x and the virtual boundary line 3y illustrated in FIG. 4 in plan view.

Next, as illustrated in FIG. 12D, masks RM1 having a width narrower than that of the recesses 31 are formed on the element isolation regions 30. The masks RM1 are formed by, for example, a known photolithography technique.

Next, using the masks RM1 as etching masks, the isolation insulating films 32 outside the masks RM1 are selectively removed, and as illustrated in FIG. 12E, gaps 34 are formed between sidewalls of each recess 31 and each isolation insulating film 32. In the first embodiment, the gaps 34 are formed on both sides of the isolation insulating film 32 in a width direction. The selective removal of the isolation insulating films 32 can be performed by a known dry etching technique.

Next, after the masks RM1 are removed, the gate insulating films 33 are formed over the first surface S1 of the semiconductor layer 20 and wall surfaces of the semiconductor layer 20 in the recesses 31 (side surfaces and a bottom surface of the recesses 31) as illustrated in FIG. 12F. The gate insulating films 33 can be formed by forming a silicon oxide film by, for example, a thermal oxidation method or a deposition method. In the first embodiment, the thermal oxidation method is used.

Next, as illustrated in FIG. 12G, a conductive film 35 as a gate material is formed on the entirety of the first surface S1 of the semiconductor layer 20 including the inside of the gaps 34 between each recess 31 and each isolation insulating film 32. As the conductive film 35, for example, a polycrystalline silicon (doped polysilicon) film into which an impurity for reducing a resistance value is introduced during or after film formation can be used. At portions where the gate insulating films 33 are formed on the semiconductor layer 20, the gate insulating films 33 are interposed between the semiconductor layer 20 and the conductive film 35. The polycrystalline silicon film can be formed by a known CVD method.

Next, the conductive film 35 is patterned using a known photolithography technique and a known dry etching technique to form the gate electrodes 36 as illustrated in FIG. 12H.

Through this process, each gate electrode 36 is formed in a shape having the head 36a provided on the first surface S1 side of the semiconductor layer 20 via the gate insulating film 33 and the legs 36b extending from the head 36a in the thickness direction (Z direction) of the semiconductor layer 20 and provided in the element isolation regions 30 adjacent to the semiconductor layer 20 via the gate insulating film 33.

Furthermore, each gate electrode 36 is formed in a shape having the leg 36b provided in the element isolation region 30 located on the virtual boundary line 3x in FIG. 4 and the leg 36b provided in the element isolation region 30 located on the virtual boundary line 3y in FIG. 4.

### Main Effects of First Embodiment

During these years, since high-resolution image sensors are demanded in the market, image sensors with reduced pixel sizes are being developed. With the development of such image sensors, many technical problems have become apparent in relation to the reduction of pixel size, but in particular, it is extremely important in basic characteristics of the image sensors to minimize decreases in sensitivity and saturation signal amount (Qs).

With regard to the sensitivity, since light incident area per pixel decreases as the pixel size decreases, an effective means is to increase film thickness of a photoelectric conversion unit (photodiode PD) responsible for photoelectric conversion, that is, to increase layer thickness of a semiconductor layer.

Since the photoelectric conversion unit also has a role of accumulating (holding) electrons (signal charge) generated as a result of photoelectric conversion, it is possible to suppress a decrease in the saturation signal amount (Qs) by adjusting a potential in the photoelectric conversion unit in addition to increasing the film thickness of the photoelectric conversion unit. The adjustment of the potential is mainly performed by adjusting impurity concentration.

Furthermore, a general CMOS image sensor includes a pixel circuit that converts signal charge held in a floating diffusion as a charge holding unit into a pixel signal and that outputs the pixel signal to a vertical signal line. The pixel circuit includes pixel transistors such as an amplifier transistor, a selection transistor, a reset transistor, and a switching transistor arranged on the same plane as a transfer transistor TR.

In a case where these pixel transistors are arranged on the same plane, however, area of the photoelectric conversion unit is relatively reduced as a result of miniaturization of a pixel, which leads to a decrease in sensitivity and saturation signal amount (Qs). By forming the pixel transistor and the photoelectric conversion unit in a multilayer structure, however, it is possible to increase volume of the photoelectric conversion unit.

The multilayer structure includes the following two structures.
(a1); The photoelectric conversion unit is embedded in the same semiconductor layer.
(a2): The pixel transistors and the photoelectric conversion unit are provided in different semiconductor layers.

In the structure of (a1), in order to transfer signal charge from the photoelectric conversion unit to the floating diffusion, it is necessary to cause potential modulation caused by a gate electrode of the transfer transistor to reach a deeper portion inside from a surface of the semiconductor layer, and therefore a field-effect transistor having a vertical structure is an effective means.

With respect to the transfer of signal charge from the photoelectric conversion unit to the floating diffusion, not only the potential modulation caused by the transfer transistor but also a potential gradient formed in the photoelectric conversion unit through adjustment of impurity concentration is required particularly in a portion far from the transfer transistor.

If the potential gradient is partially in a reverse gradient state, transfer of signal charges is hindered, thereby reducing output of a pixel signal.

Furthermore, since the output of a pixel signal “varies” for each pixel, non-uniformity of an image to be finally output deteriorates, that is, image quality deteriorates.

Due to the following effects, the deterioration of image quality becomes significant as the pixel size decreases.
(b1); An effect of manufacturing variation for each pixel relatively increases.
(b2); In order to establish a p-type semiconductor region and an n-type semiconductor region of the photoelectric conversion unit with a narrow pitch, it is necessary to increase the impurity concentration; however, when the impurity concentration is increased, an effect of discrete dopants (fluctuation of impurities) on a charge transfer path increases, and the transfer of signal charge is hindered.

In order to avoid these problems, it is necessary to further increase a potential gradient in design, but this directly leads to a decrease in charge holding capability, that is, a decrease in the saturation signal amount (Qs).

With respect to charge transfer in the vicinity of the legs of the gate electrode, arrangement positions of the legs are also important.

In general, the legs of the gate electrode are circular and disposed in such a way as to bite into the photoelectric conversion unit, but such arrangement easily causes deteriorations such as dark current, white spots, and the like due to an interface between the sidewalls of the legs of the gate electrode and the semiconductor layer, and it is necessary to secure hole concentration through impurity injection.

During this process, however, the impurity concentration increases, which leads to the above-described problems of discrete dopants and a reverse gradient described above.

Furthermore, by disposing the legs as structures on the charge transfer path, the charge transfer path becomes complex, and variation in each pixel tend to deteriorate.

In each transfer transistor TR provided in the solid-state imaging device 1A according to the first embodiment, on the other hand, the legs 36b of the gate electrode 36 are arranged in the pixel isolation region 30. As a result, the charge transfer path R₁ for transferring signal charge from the photoelectric conversion unit 25 to the floating diffusion FD can be simplified, and an effect of potential modulation can be increased. With to the solid-state imaging device 1A according to the first embodiment, therefore, it is possible to secure robust (stable) transfer capability.

FIG. 11 is a diagram illustrating a potential of signal charge in a charge transfer path. Data A is a potential in the case of the transfer transistor TR of the present technology, and data B is a potential in the case of a transfer transistor in a comparative example. The transfer transistor in the comparative example has a configuration in which legs of a gate electrode are located in the charge transfer path.

As can be seen from FIG. 11, the data A has a flatter potential than the data B, and it is clear that application of the present technology is effective.

### Second Embodiment

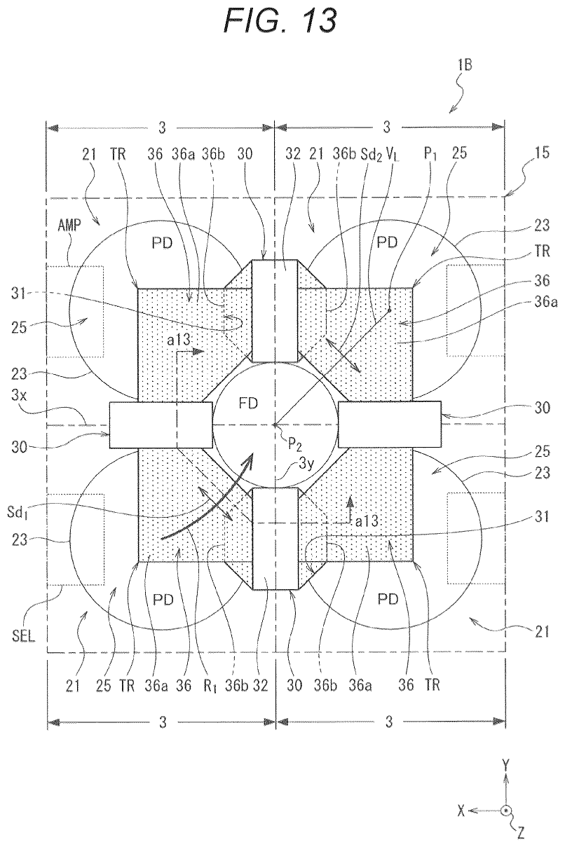

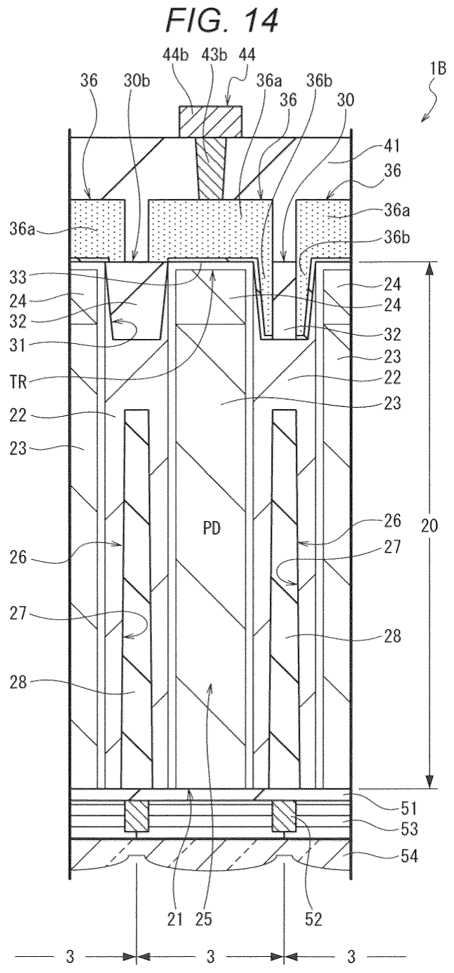

As illustrated in FIGS. 13 and 14, a solid-state imaging device 1B according to a second embodiment of the present technology basically has a configuration similar to that of the solid-state imaging device 1A according to the first embodiment described above, and configuration of the gate electrode 36 of the transfer transistor TR is different.

That is, as illustrated in FIGS. 4 and 5, the gate electrode 36 of the transfer transistor TR according to the above-described first embodiment has a configuration in which the legs 36b are provided on each of the two end sides of the head 36a in the direction (see FIG. 9: intersecting direction Sd₁) intersecting the charge transfer path R₁ in plan view.

As illustrated in FIGS. 13 and 14, on the other hand, the gate electrode 36 of the transfer transistor TR according to the second embodiment has a configuration in which a leg 36b is provided on one of the two end sides of the head 36a in the direction (intersecting direction Sd₁) intersecting the charge transfer path R₁ in plan view. In other words, the gate electrode 36 of the transfer transistor TR according to the second embodiment has a configuration in which the leg 36b is provided on one of the two end sides of the head 36a in the direction (intersecting direction Sd₂) intersecting the virtual line V_{L} connecting the central portion P₁ of the photoelectric conversion unit 25 and the central portion P₂ of the floating diffusion FD in plan view. That is, the transfer transistor TR according to the second embodiment is a single lung type (single type) in which one inversion layer 37 is formed in the semiconductor layer 20 by the one leg 36b of the gate electrode 36. Other configurations are substantially similar to those of the first embodiment described above.

The solid-state imaging device 1B according to the second embodiment can also produce effects similar to the effects produced by the solid-state imaging device 1A according to the first embodiment described above.

Note that a planar pattern of element isolation regions 30 at positions overlapping the virtual boundary line 3y in plan view has an octagonal shape as in the first embodiment described above. A planar pattern of element isolation regions 30 at positions overlapping the virtual boundary line 3x, on the other hand, is rectangular.

### Third Embodiment

A solid-state imaging device 1C according to a third embodiment of the present technology is basically similar in configuration to the solid-state imaging device 1A according to the first embodiment described above, but is different in the following configuration.

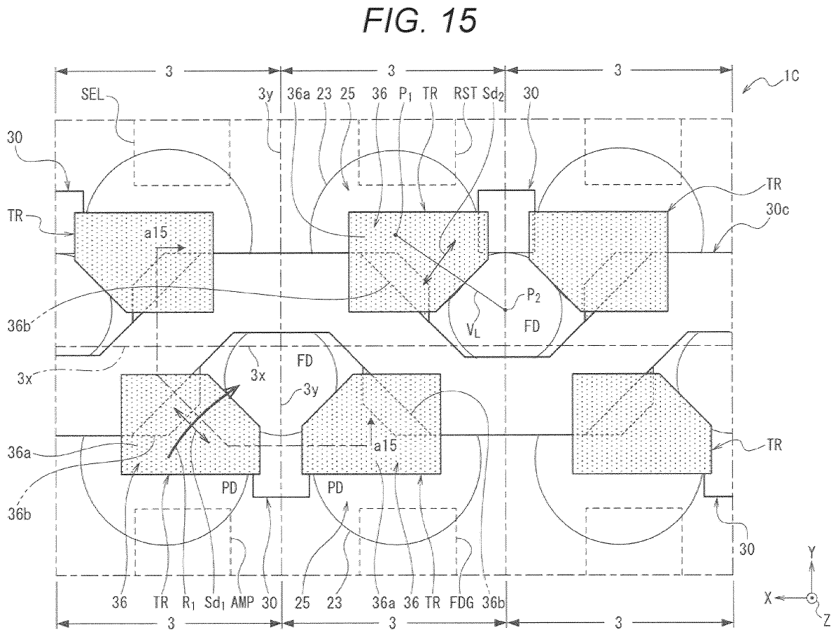

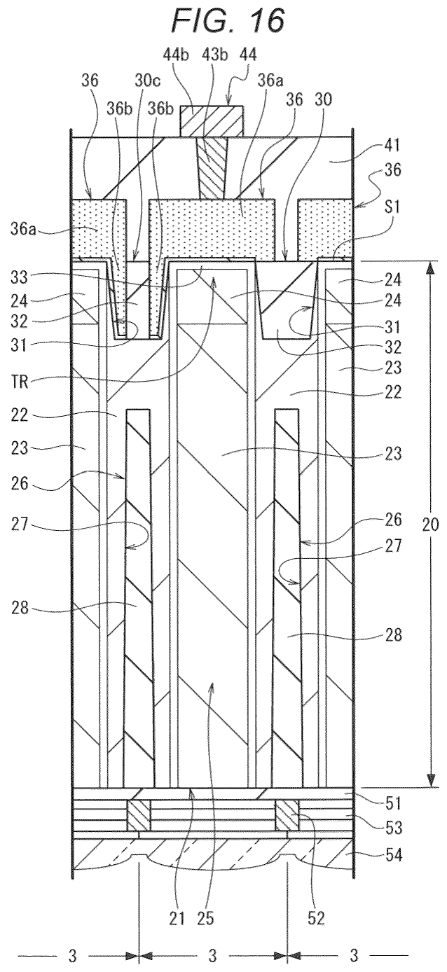

That is, as illustrated in FIGS. 15 and 16, the solid-state imaging device 1C according to the third embodiment includes element isolation regions 30c instead of the element isolation regions 30 according to the first embodiment described above. In addition, in the third embodiment, the number of pixels 3 that share one floating diffusion FD and the configuration of the gate electrode 36 of the transfer transistor TR are different.

As illustrated in FIGS. 15 and 16, each element isolation region 30c has a planar pattern extending in a zigzag (ziczac) shape along the virtual boundary line 3x between two pixels 3 adjacent to each other in the Y direction. In addition, two pixels 3 adjacent to each other in the X direction share one floating diffusion FD. In addition, similarly to the above-described second embodiment, the gate electrode 36 of the transfer transistor TR has a single lung shape in which one inversion layer 37 is formed in the semiconductor layer 20 by the one leg 36b of the gate electrode 36.

The solid-state imaging device 1C according to the third embodiment can also produce effects similar to the effects produced by the solid-state imaging device 1A according to the first embodiment described above.

### Fourth Embodiment

A solid-state imaging device 1D according to a fourth embodiment of the present technology is basically similar in configuration to the solid-state imaging device 1A according to the first embodiment described above, but is different in the following configuration.

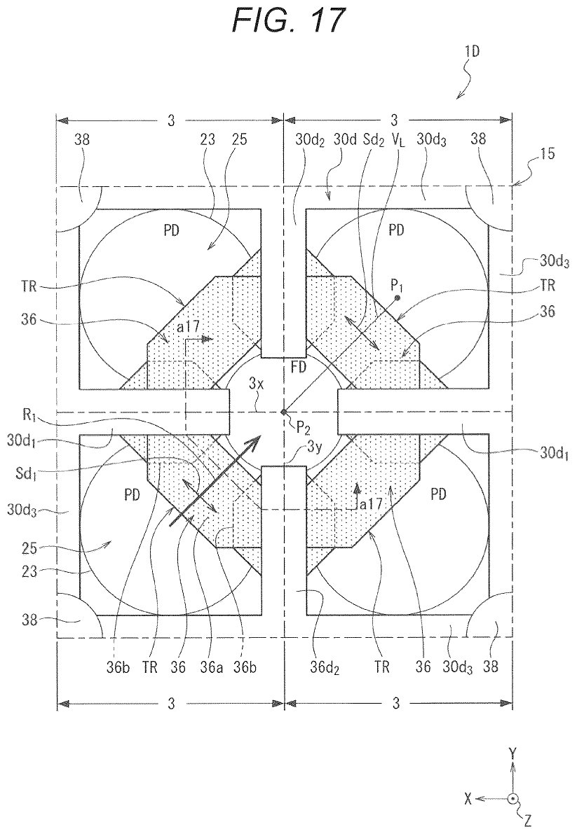

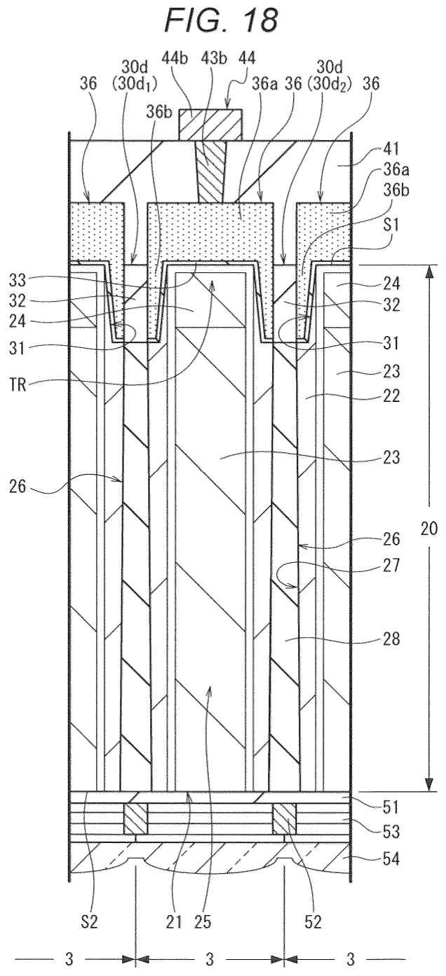

That is, as illustrated in FIGS. 17 and 18, the solid-state imaging device 1D according to the fourth embodiment includes element isolation regions 30d instead of the element isolation regions 30 according to the first embodiment described above. In addition, in the third embodiment, the pixel transistors (AMP, SEL, RST, and FDG) included in the pixel circuit 16 in FIG. 3A are not formed in the semiconductor layer 20, but are formed in another semiconductor layer overlapping the semiconductor layer 20. In the first embodiment, the semiconductor layer 20 corresponds to a specific example of a “first semiconductor layer” of the present technology, and the other semiconductor layer overlapping the semiconductor layer 20 corresponds to a specific example of a “second semiconductor layer” of the present technology. The solid-state imaging device 1D according to the fourth embodiment, therefore, includes a semiconductor layer (first semiconductor layer) 20 provided with the photoelectric conversion units 21, the floating diffusions FD, the transfer transistors TR, and the like and the second semiconductor layer provided in such a way as to overlap the semiconductor layer 20. In addition, the pixel transistors (AMP, SEL, RST, and FDG) of the pixel circuit 16 are provided in the second semiconductor layer.

As illustrated in FIGS. 17 and 18, the element isolation regions 30d include two first portions 30d₁ arranged at positions overlapping the virtual boundary line 3x with the floating diffusion FD interposed therebetween, two second portions 30d₂ arranged at positions overlapping the virtual boundary line 3y with the floating diffusion FD interposed therebetween, and third portions 30d₃ surrounding the periphery of the four pixels 3. In addition, sides of the two first portions 30d₁ opposite floating diffusion FD sides are connected to the third portions 30d₃, and sides of the two second portions 30d₂ opposite floating diffusion FD sides are connected to the third portions 30d₃.

In addition, the element isolation regions 30d including the first to third portions 30d₁, 30d₂, and 30d₃ are connected to the pixel isolation regions 26.

In addition, in each transfer transistor TR, one of the two legs 36b of the gate electrode 36 is provided in the first portion 30d₁ of the element isolation region 30d, and the other leg 36b is provided in the second portion 30d₂ of the element isolation region 30d.

The solid-state imaging device 1D according to the fourth embodiment can also produce effects similar to the effects produced by the solid-state imaging device 1A according to the first embodiment described above.

Note that, as illustrated in FIG. 17, power supply contact regions 38 for supplying a potential to the semiconductor layer 20 are provided on sides opposite floating diffusion FD sides of the pixels 3.

### Fifth Embodiment

A solid-state imaging device 1E according to a fifth embodiment of the present technology is basically similar in configuration to the solid-state imaging device 1A according to the first embodiment, but is different in the following configuration.

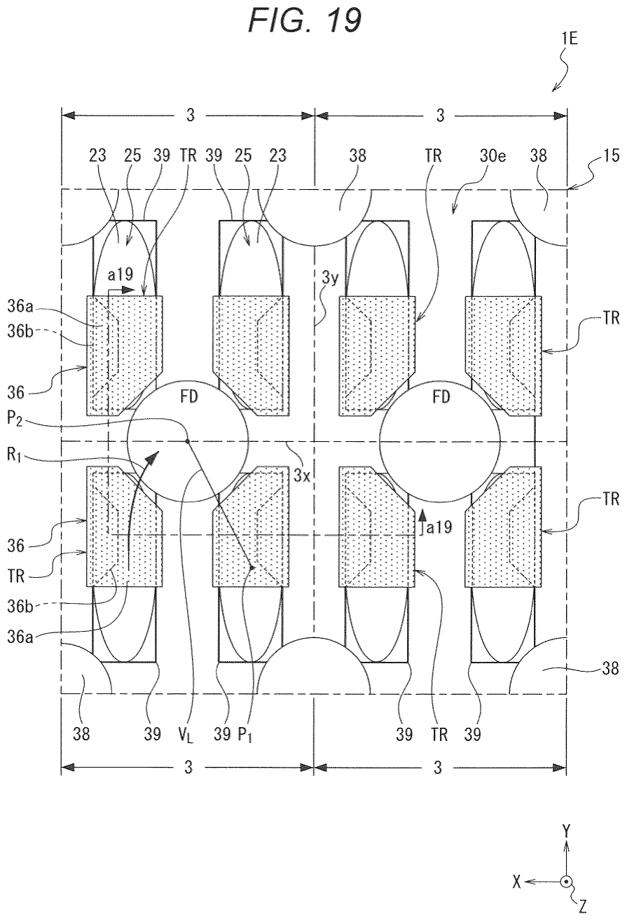

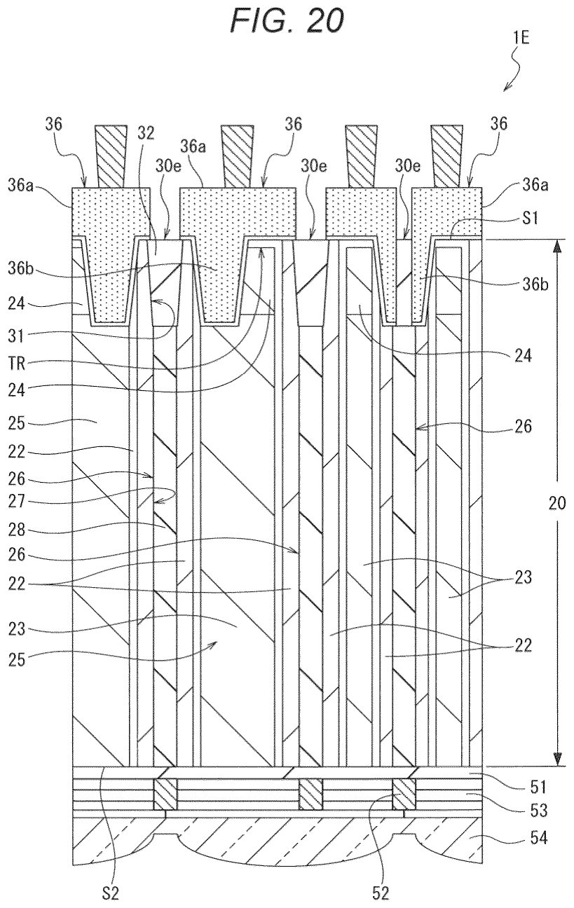

That is, as illustrated in FIGS. 19 and 20, the solid-state imaging device 1E according to the fifth embodiment includes element isolation regions 30e instead of the element isolation regions 30 according to the first embodiment described above. In addition, in the fifth embodiment, too, the pixel transistors (AMP, SEL, RST, and FDG) included in the pixel circuit 16 in FIG. 3A are not formed in the semiconductor layer 20, but are formed in another semiconductor layer overlapping the semiconductor layer 20.

As illustrated in FIGS. 19 and 20, the element isolation regions 30e are provided on the first surface S1 side of the semiconductor layer in such a way as to cover the first surface of the semiconductor layer. In addition, the element isolation regions 30e are provided with two windows 39 for each pixel 3. The two windows 39 are arranged side by side in the X direction.

The semiconductor layer 20 in each of the two windows 39 is provided with, as in the above-described first embodiment, a p-type semiconductor region 22, an n-type semiconductor region 23, an overflow drain region 24, a photoelectric conversion unit 25, a transfer transistor TR, and the like.

In each pixel block 15 including four pixels 3, a floating diffusion FD is disposed between two pixels 3 arranged adjacent to each other in the Y direction. In addition, the transfer transistors TR in the windows 39 of each of the two pixels 3 are arranged in such a way as to surround the floating diffusion FD.

In each transfer transistor TR according to the fifth embodiment, too, the leg 36b of the gate electrode 36 is provided in the element isolation region 30e. In addition, in the fifth embodiment, the number of legs 36b of each gate electrode 36 is one, and each transfer transistor TR according to the fifth embodiment is of a single lung type (single type) in which one inversion layer 37 is formed in the semiconductor layer 20 by the one leg 36b of the gate electrode 36.

The solid-state imaging device 1E according to the fifth embodiment can also produce effects similar to the effects produced by the solid-state imaging device 1A according to the first embodiment described above.

Note that, as illustrated in FIG. 19, power supply contact regions 38 for supplying a potential to the semiconductor layer 20 are provided on sides opposite floating diffusion FD sides of the pixels 3.

Furthermore, as illustrated in FIG. 20, the element isolation regions 30e are connected to the pixel isolation regions 26.

### Sixth Embodiment

A solid-state imaging device 1F according to a sixth embodiment of the present technology is basically similar in configuration to the solid-state imaging device 1A according to the first embodiment, but is different in the following configuration.

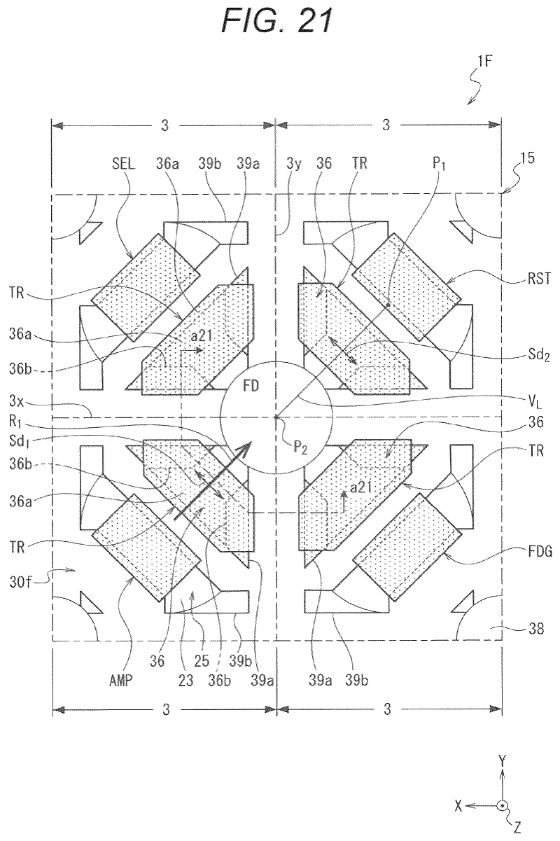

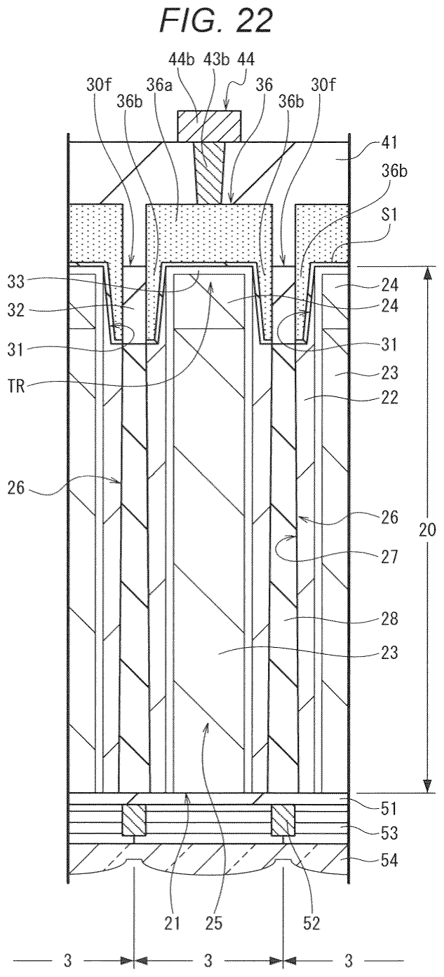

That is, as illustrated in FIGS. 21 and 22, the solid-state imaging device 1E according to the fifth embodiment includes element isolation regions 30f instead of the element isolation regions 30 according to the first embodiment described above.

As illustrated in FIGS. 21 and 22, the element isolation regions 30f are provided on the first surface S1 side of the semiconductor layer 20 in such a way as to cover the first surface S1 of the semiconductor layer 20. In addition, the element isolation regions 30f are provided with two windows 39a and 39b for each pixel 3. Of the two windows 39a and 39b, the window 39a is arranged close to the floating diffusion FD side of the pixel 3 in plan view, and the window 39b is arranged at a central portion of the pixel 3 in plan view.

The semiconductor layer 20 in the window 39a is provided with, as in the above-described first embodiment, a p-type semiconductor region 22, an n-type semiconductor region 23, an overflow drain region 24, a photoelectric conversion unit 25, a transfer transistor TR, and the like. In addition, the semiconductor layer 20 in the window 39b is provided with an n-type semiconductor region 23, an overflow drain region 24, a photoelectric conversion unit 25, pixel transistors (AMP, SEL, RST, and FDG), and the like.

As in the first embodiment described above, the floating diffusion FD is disposed in a region where the virtual boundary line 3x and the virtual boundary line 3y intersect. In addition, the gate electrode 36 of the transfer transistor TR of each of the four pixels 3 included in the pixel block 15 is disposed outside the floating diffusion FD in such a way as to surround the floating diffusion FD.

In each transfer transistor TR according to the sixth embodiment, too, the legs 36b of the gate electrode 36 are provided in the element isolation regions 30f. In addition, in the sixth embodiment, the number of legs 36b of each gate electrode 36 is two, and each transfer transistor TR according to the sixth embodiment is of a double lung type (dual type) in which two inversion layers 37 are formed in the semiconductor layer 20 by the two legs 36b of the gate electrode 36.

The solid-state imaging device 1F according to the sixth embodiment can also produce effects similar to the effects produced by the solid-state imaging device 1A according to the first embodiment described above.

Note that, as illustrated in FIG. 21, power supply contact regions 38 for supplying a potential to the semiconductor layer 20 are provided on sides opposite floating diffusion FD sides of the pixels 3.

Furthermore, as illustrated in FIG. 22, the element isolation regions 30e are connected to the pixel isolation regions 26.

### Seventh Embodiment

### Examples of Application to Electronic Apparatuses

The present technology (technology of the present disclosure) can be applied to, for example, various electronic apparatuses such as imaging apparatuses including digital still cameras and digital video cameras, mobile phones having an imaging function, and other apparatuses having an imaging function.

FIG. 23 is a diagram illustrating a schematic configuration of an electronic apparatus (e.g., a camera) according to a tenth embodiment of the present technology.

As illustrated in FIG. 23, an electronic apparatus 100 includes a solid-state imaging device 101, an optical lens 102, a shutter device 103, a drive circuit 104, and a signal processing circuit 105. The electronic apparatus 100 is an embodiment in a case where one of the solid-state imaging devices 1A to 1F according to the first to sixth embodiments of the present technology is used as the solid-state imaging device 101 in an electronic apparatus (e.g., a camera).

The optical lens 102 forms an image of image light (incident light 106) from a subject on an imaging plane of the solid-state imaging device 101. As a result, signal charge is accumulated in the solid-state imaging device 101 over a certain period. The shutter device 103 controls a light radiation period and a light shielding period for the solid-state imaging device 101. The drive circuit 104 supplies a drive signal for controlling a transfer operation of the solid-state imaging device 101 and a shutter operation of the shutter device 103. A signal of the solid-state imaging device 101 is transferred in accordance with the drive signal (timing signal) supplied from the drive circuit 104. The signal processing circuit 105 performs various types of signal processing on a signal (pixel signal) output from the solid-state imaging device 101. A video signal subjected to the signal processing is stored into a storage medium such as a memory or output to a monitor.

With such a configuration, in the electronic apparatus 100 according to the sixth embodiment, stable transfer capability is secured in the solid-state imaging devices 1A to 1F, thereby improving image quality.

Note that the electronic apparatus 100 to which the solid-state imaging devices according to the embodiments described above can be applied is not limited to a camera, and the solid-state imaging devices can also be applied to other electronic apparatuses. For example, the solid-state imaging devices may be applied to imaging devices such as camera modules for mobile apparatuses such as mobile phones and tablet terminals.

Furthermore, the present technology can be applied to photodetectors in general including not only the above-described solid-state imaging device as the image sensor but also a ranging sensor that is also called a time-of-flight (ToF) sensor and that measures a distance and the like. The ranging sensor is a sensor that emits radiation light onto an object, that detects the radiation light reflected from a surface of the object, and that calculates a distance to the object on the basis of a flight time from the emission of the radiation light to reception of the reflected light. The above-described structure of the transfer transistor can be employed as the structure of a transfer transistor of the ranging sensor.

### Example of Application to Mobile Object

The present technology (technology of the present disclosure) can be applied to various products. For example, the technology of the present disclosure may be implemented as a device mounted on a mobile object of one of the following types: an automobile, an electric vehicle, a hybrid electric vehicle, a motorcycle, a bicycle, a personal mobility, an airplane, a drone, a vessel, a robot, or the like.

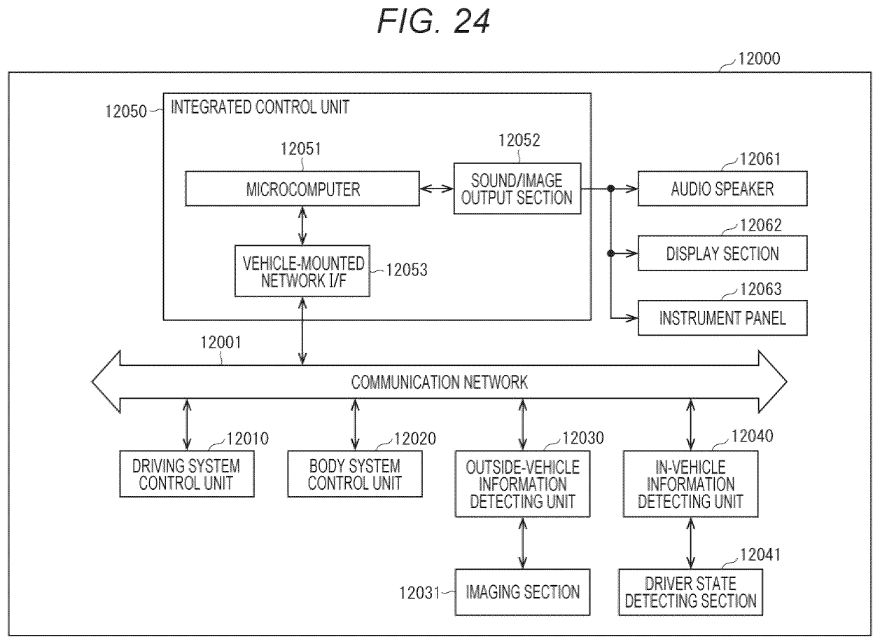

FIG. 24 is a block diagram illustrating an example of a schematic configuration of a vehicle control system as an example of a mobile object control system to which the technology of the present disclosure can be applied.

The vehicle control system 12000 includes a plurality of electronic control units connected to each other via a communication network 12001. In the example illustrated in FIG. 24, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 24, an audio speaker 12061, a display section 12062, and an instrument panel 12063 are illustrated as the output device. The display section 12062 may, for example, include at least one of an on-board display and a head-up display.

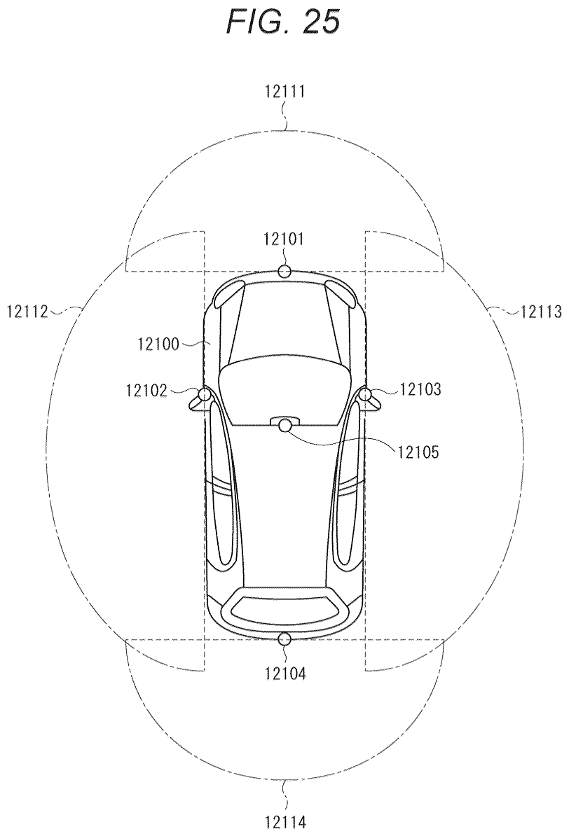

FIG. 25 is a diagram illustrating an example of installation positions of the imaging section 12031.

In FIG. 25, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 25 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the present technology can be applied has been described above. The present technology can be applied to the imaging section 12031 among the configurations described above. More specifically, the solid-state imaging device 1A in FIG. 1 can be applied to the imaging section 12031. By applying the present technology to the imaging section 12031, better images can be captured, thereby reducing fatigue of the driver.

### Example of Application to Endoscopic Surgery System

The present technology (technology of the present disclosure) can be applied to various products. For example, the technology of the present disclosure may be applied to an endoscopic surgery system.

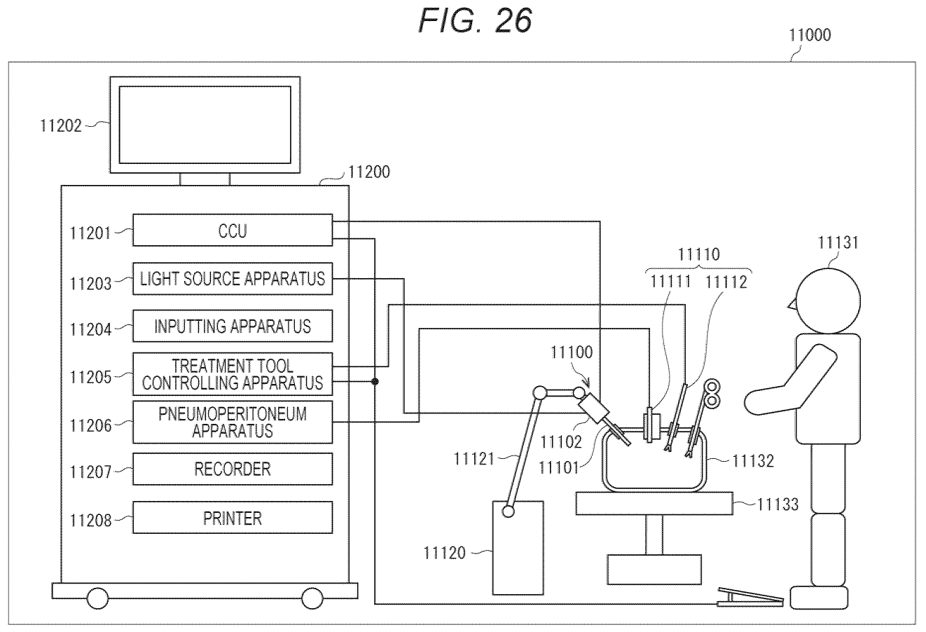

FIG. 26 is a diagram illustrating an example of a schematic configuration of the endoscopic surgery system to which the technology of the present disclosure (present technology) can be applied.

FIG. 26 illustrates a state in which a surgeon (medical doctor) 11131 is performing surgery for a patient 11132 on a patient bed 11133 using an endoscopic surgery system 11000. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

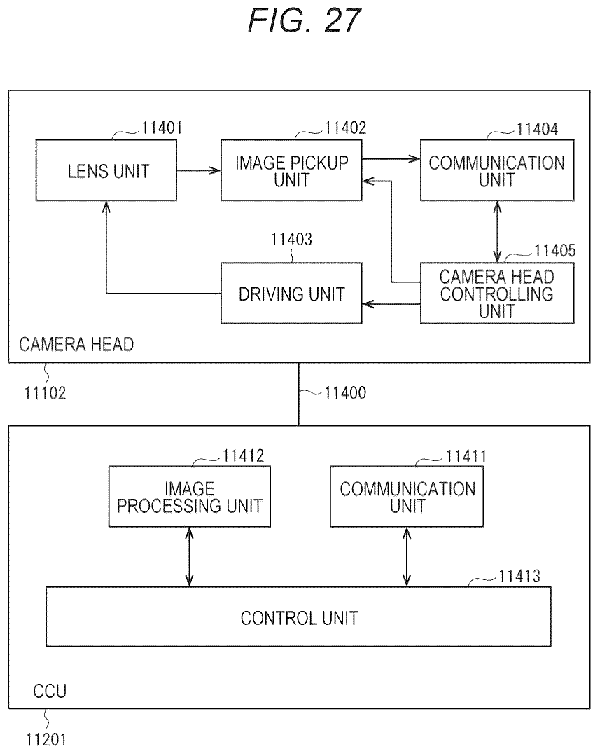

FIG. 27 is a block diagram illustrating an example of a functional configuration of the camera head 11102 and the CCU 11201 illustrated in FIG. 26.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the present technology can be applied has been described above. The present technology can be applied to the image pickup unit 11402 among the configurations described above. More specifically, the solid-state imaging device 1A in FIG. 1 can be applied to the image pickup unit 10402. By applying the present technology to the image pickup unit 10402, for example, clearer images of a surgical region can be obtained, and a surgeon can reliably check the surgical region.

Note that although an endoscopic surgery system has been described as an example herein, the technology of the present disclosure may also be applied to, for example, a microscopic surgery system or the like.

Note that the present technology may also have the following configurations.
(1)

A photodetector including:

a semiconductor layer having a first surface and a second surface located on opposite sides;

a photoelectric conversion unit that is provided in the semiconductor layer and that converts, through photoelectric conversion, light incident from a second surface side of the semiconductor layer;

a charge holding unit provided on a first surface side of the semiconductor layer;

a transfer transistor that includes a gate electrode and that transfers signal charge generated by the photoelectric conversion unit through the photoelectric conversion to the charge holding unit; and

an isolation region provided on the first surface side of the semiconductor layer,

in which the gate electrode includes

a head provided on the first surface side of the semiconductor layer, and

legs that extend from the head in a thickness direction of the semiconductor layer and that are provided in the isolation region adjacent to the semiconductor layer via a gate insulating film.
(2)

The photodetector according to (1), in which the legs of the gate electrode are provided on at least one of two end sides of the head in a direction intersecting, in plan view, a charge transfer path through which the transfer transistor transfers signal charge from the photoelectric conversion unit to the charge holding unit.
(3)

The photodetector according to (1), in which

the head of the gate electrode is disposed at a position overlapping a virtual line connecting a central portion of the photoelectric conversion unit and a central portion of the charge holding unit in plan view, and

the legs of the gate electrode are provided on at least one of two end sides of the head in a direction intersecting the virtual line in plan view.
(4)

The photodetector according to (1), in which the legs of the gate electrode are disposed on one of two sides of the transfer path in plan view.
(5)

The photodetector according to any one of (1) to (4), further including:

a pixel array unit repeatedly arranged in each of a first direction and a second direction in which pixels intersect with each other,

in which each of the plurality of pixels includes a photoelectric conversion region defined by a pixel isolation region extending in the thickness direction of the semiconductor layer, and

the photoelectric conversion region includes the photoelectric conversion unit, the charge holding unit, and the transfer transistor.
(6)

The photodetector according to (5), in which the pixel isolation region is separated from the isolation region.
(7)

The photodetector according to (5), in which the pixel isolation region is connected to the isolation region.
(8)

The photodetector according to (5), in which the isolation region is disposed between two photoelectric conversion regions adjacent to each other in plan view.
(9)

The photodetector according to (5), in which the isolation region extends along one of the first direction and the second direction in a zigzag shape.
(10)

The photodetector according to any one of (1) to (9), in which the isolation region includes a recess provided on the first surface side of the semiconductor layer and an isolation insulating film provided in the recess.
(11)

The photodetector according to any one of (1) to (10), further including:

a pixel circuit electrically connected to the charge holding unit,

in which a pixel transistor included in the pixel circuit is provided in the semiconductor layer.
(12)

The photodetector according to any one of (1) to (11), the semiconductor layer being a first semiconductor layer, the photodetector further including:

a second semiconductor layer provided in such a way as to overlap the first semiconductor layer in plan view; and

a pixel circuit electrically connected to the charge holding unit,

in which a pixel transistor included in the pixel circuit is provided in the second semiconductor layer.
(13)

An electronic apparatus including:

a photodetector;

an optical lens that forms an image of image light from a subject on an imaging plane of the photodetector;

a signal processing circuit that performs signal processing on a signal output from the photodetector,

in which the photodetector includes

a semiconductor layer having a first surface and a second surface located on opposite sides,

a photoelectric conversion unit that is provided in the semiconductor layer and that converts, through photoelectric conversion, light incident from a second surface side of the semiconductor layer,

a charge holding unit provided on a first surface side of the semiconductor layer,

a transfer transistor that includes a gate electrode and that transfers signal charge generated by the photoelectric conversion unit through the photoelectric conversion to the charge holding unit, and

an isolation region provided on the first surface side of the semiconductor layer, and

the gate electrode includes

a head provided on the first surface side of the semiconductor layer, and

legs that extend from the head in a thickness direction of the semiconductor layer and that are provided in the isolation region adjacent to the semiconductor layer via a gate insulating film.

The scope of the present technology is not limited to the exemplary embodiments illustrated in the drawings and described above, but also includes all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A Solid-state imaging device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
12 Horizontal signal line
13 Logic circuit
14 Bonding pad
15 Pixel block
16 Pixel circuit
20 Semiconductor layer
21 Photoelectric conversion region
22 p-type semiconductor region
23 n-type semiconductor region
24 Overflow drain region
25 Photoelectric conversion unit
26 Pixel isolation region
27 Recess
28 Isolation insulating film
30 Element isolation region (isolation region)
31 Recess
32 Isolation insulating film
33 Gate insulating film
34 Gap
35 Conductive film
36 Gate electrode
36a Head (planar electrode)
36b Leg (vertical electrode)
37 Inversion layer
38 Contact region
39, 39a, 39b Window
41 Interlayer insulating film
42a, 42b Through hole
43a, 43b Contact electrode
44 Wiring layer
42a, 42b Wire
AMP Amplifier transistor
FD Floating diffusion (charge holding unit)
FDG Switching transistor
PD Photoelectric conversion element
RST Reset transistor
SEL Selection transistor
TR Transfer transistor
V_{L} Virtual line
P₁, P₂ Central portion
Sd₁, Sd₂ Intersecting direction
R₁ Charge transfer path

What is claimed is:

1. A photodetector, comprising:
a semiconductor layer having a first surface and a second surface located on opposite sides;
a photoelectric conversion unit that is provided in the semiconductor layer and that converts, through photoelectric conversion, light incident from a second surface side of the semiconductor layer;
a charge holding unit provided on a first surface side of the semiconductor layer;
a transfer transistor that includes a gate electrode and that transfers signal charge generated by the photoelectric conversion unit through the photoelectric conversion to the charge holding unit; and
an isolation region provided on the first surface side of the semiconductor layer,
wherein the gate electrode includes
a head provided on the first surface side of the semiconductor layer, and
legs that extend from the head in a thickness direction of the semiconductor layer and that are provided in the isolation region adjacent to the semiconductor layer via a gate insulating film.

2. The photodetector according to claim 1, wherein the legs of the gate electrode are provided on at least one of two end sides of the head in a direction intersecting, in plan view, a charge transfer path through which the transfer transistor transfers signal charge from the photoelectric conversion unit to the charge holding unit.

3. The photodetector according to claim 1, wherein
the head of the gate electrode is disposed at a position overlapping a virtual line connecting a central portion of the photoelectric conversion unit and a central portion of the charge holding unit in plan view, and
the legs of the gate electrode are provided on at least one of two end sides of the head in a direction intersecting the virtual line in plan view.

4. The photodetector according to claim 1, wherein the legs of the gate electrode are disposed on one of two sides of the transfer path in plan view.

5. The photodetector according to claim 1, further comprising:
a pixel array unit repeatedly arranged in each of a first direction and a second direction in which pixels intersect with each other,
wherein each of the plurality of pixels includes a photoelectric conversion region defined by a pixel isolation region extending in the thickness direction of the semiconductor layer, and
the photoelectric conversion region includes the photoelectric conversion unit, the charge holding unit, and the transfer transistor.

6. The photodetector according to claim 5, wherein the pixel isolation region is separated from the isolation region.

7. The photodetector according to claim 5, wherein the pixel isolation region is connected to the isolation region.

8. The photodetector according to claim 5, wherein the isolation region is disposed between two photoelectric conversion regions adjacent to each other in plan view.

9. The photodetector according to claim 5, wherein the isolation region extends along one of the first direction and the second direction in a zigzag shape.

10. The photodetector according to claim 1, wherein the isolation region includes a recess provided on the first surface side of the semiconductor layer and an isolation insulating film provided in the recess.

11. The photodetector according to claim 1, further comprising:
a pixel circuit electrically connected to the charge holding unit,
wherein a pixel transistor included in the pixel circuit is provided in the semiconductor layer.

12. The photodetector according to claim 1, the semiconductor layer being a first semiconductor layer, the photodetector further comprising:
a second semiconductor layer provided in such a way as to overlap the first semiconductor layer in plan view; and
a pixel circuit electrically connected to the charge holding unit,
wherein a pixel transistor included in the pixel circuit is provided in the second semiconductor layer.

13. An electronic apparatus, comprising:
a photodetector;
an optical lens that forms an image of image light from a subject on an imaging plane of the photodetector; and
a signal processing circuit that performs signal processing on a signal output from the photodetector,
wherein the photodetector includes
a semiconductor layer having a first surface and a second surface located on opposite sides,
a photoelectric conversion unit that is provided in the semiconductor layer and that converts, through photoelectric conversion, light incident from a second surface side of the semiconductor layer,
a charge holding unit provided on a first surface side of the semiconductor layer,
a transfer transistor that includes a gate electrode and that transfers signal charge generated by the photoelectric conversion unit through the photoelectric conversion to the charge holding unit, and
an isolation region provided on the first surface side of the semiconductor layer, and
the gate electrode includes
a head provided on the first surface side of the semiconductor layer, and
legs that extend from the head in a thickness direction of the semiconductor layer and that are provided in the isolation region adjacent to the semiconductor layer via a gate insulating film.
